(19) United States
(12) Patent Application Publication
(10) Pub. No.: US 2025/0072193 A1
(43) Pub. Date: Feb. 27, 2025

(54) DISPLAY DEVICE

(71) Applicant: Samsung Display Co., LTD., Yongin-si (KR)

(72) Inventors: Ki Chang EOM, Yongin-si (KR); Sung Hwan KIM, Yongin-si (KR)

(21) Appl. No.: 18/810,151

(22) Filed: Aug. 20, 2024

(30) Foreign Application Priority Data
Aug. 25, 2023 (KR) 10-2023-0112044

(51) Int. Cl. H01L 33/62; H01L 25/16

(52) U.S. Cl. CPC H01L 33/62; H01L 25/167

(57) ABSTRACT

A display device includes a substrate, a pixel electrode provided on the substrate, a light emitting element provided on the pixel electrode, and including a first semiconductor layer, a second semiconductor layer, and an active layer interposed between the first semiconductor layer and the second semiconductor layer, a connection electrode provided between the pixel electrode and the light emitting element, an adhesive layer provided between the connection electrode and the pixel electrode, and a common electrode provided on the light emitting element. The first semiconductor layer includes a body portion adjacent to the active layer, and a support portion protruding from the body portion toward the pixel electrode, and the adhesive layer overlaps the support portion of the first semiconductor layer in a horizontal direction of the substrate.

### CROSS-REFERENCE TO RELATED APPLICATION

This application claims priority from Korean Patent Application No. 10-2023-0112044 filed on Aug. 25, 2023, in the Korean Intellectual Property Office, and all the benefits accruing therefrom under 35 U.S.C. 119, the entire content of which is herein incorporated by reference.

### BACKGROUND

### 1. Technical Field

One or more aspects of embodiments of the present disclosure are directed toward a display device.

### 2. Description of the Related Art

The importance of display devices has been steadily increasing with the development of multimedia technology. In response thereto, various types (or kinds) of display devices such as an organic light emitting display (OLED), a liquid crystal display (LCD) and/or the like have been utilized.

A display device is a device for displaying an image, and may include a display panel, such as an organic light emitting display panel and/or a liquid crystal display panel. The light emitting display panel may include light emitting elements, e.g., light emitting diodes (LED), and examples of the light emitting diode may include an organic light emitting diode (OLED) utilizing an organic material as a light emitting material and an inorganic light emitting diode utilizing an inorganic material as a light emitting material.

### SUMMARY

One or more aspects of embodiments of the present disclosure are directed toward a display device with improved bonding yield between a light emitting element and a pixel electrode.

One or more aspects of embodiments of the present disclosure are also directed toward a display device with improved color purity and brightness.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, a display device comprises a substrate; a pixel electrode on the substrate; a light emitting element on the pixel electrode, and comprising a first semiconductor layer, a second semiconductor layer, and an active layer between the first semiconductor layer and the second semiconductor layer; a connection electrode between the pixel electrode and the light emitting element; an adhesive layer between the connection electrode and the pixel electrode; and a common electrode on the light emitting element, wherein the first semiconductor layer comprises a body portion adjacent to the active layer, and a support portion protruding from the body portion toward the pixel electrode, and the adhesive layer overlaps the support portion of the first semiconductor layer in a horizontal direction of the substrate.

The support portion of the first semiconductor layer may be at a position adjacent to an edge (e.g., a peripheral circumference) of the body portion.

A thickness of the support portion of the first semiconductor layer may be equal to or greater than a thickness of the connection electrode.

The support portion of the first semiconductor layer may be in contact with the pixel electrode.

The body portion and the support portion of the first semiconductor layer may be integral with each other.

The connection electrode may be surrounded by the support portion (e.g., the support portion may be around the connection electrode).

The support portion of the first semiconductor layer may comprise a first pillar, and a second pillar facing the first pillar, and the adhesive layer and the connection electrode may be between the first pillar and the second pillar of the support portion.

The first pillar and the second pillar may be spaced apart from each other in a plan view.

A width of the adhesive layer may be greater than a distance between the first pillar and the second pillar.

A space between the body portion of the first semiconductor layer and the adhesive layer may be empty.

A space between the body portion of the first semiconductor layer and the adhesive layer may be empty or may include a via layer.

A cross section of the support portion of the first semiconductor layer may be square, pentagonal, or hexagonal.

The adhesive layer may contain solder.

The pixel electrode may contain glass.

According to one or more embodiments of the present disclosure, a display device comprises a substrate; a first pixel electrode on the substrate and comprising a groove; an adhesive layer on the groove of the first pixel electrode; a connection electrode on the adhesive layer; a first light emitting element on the connection electrode, and comprising a first semiconductor layer, a second semiconductor layer, and an active layer between the first semiconductor layer and the second semiconductor layer; a common electrode on the first light emitting element; and a first wavelength conversion layer on the common electrode, the first wavelength conversion layer overlapping the first light emitting element, wherein the connection electrode, the first light emitting element, and the first wavelength conversion layer overlap the groove of the first pixel electrode.

A width of the adhesive layer may be equal to or greater than a width of the groove of the first pixel electrode.

The display device may further include a bank layer on the first pixel electrode, the bank layer not overlapping the groove of the first pixel electrode; and a light blocking layer on the common electrode, and overlapping the bank layer.

The display device may further include a second pixel electrode on the substrate and spaced apart from the first pixel electrode; a second light emitting element on the connection electrode, the second light emitting element comprising a first semiconductor layer, a second semiconductor layer, and an active layer between the first semiconductor layer and the second semiconductor layer; and a light transmission layer on the common electrode, and overlapping the second light emitting element.

The first semiconductor layer of the first light emitting element may include a body portion adjacent to the active layer, and a support portion protruding from the body portion toward the first pixel electrode, and the support portion may be in contact with the first pixel electrode.

The support portion of the first semiconductor layer may comprise a first pillar, and a second pillar facing the first pillar, and a width of the groove of the first pixel electrode may be equal to or smaller than a distance between the first pillar and the second pillar.

A display device according to one or more embodiments includes a support portion that protrudes from a bottom surface of a light emitting element, so that the light emitting element may be stably suitably connected to a pixel electrode without falling over. Accordingly, the bonding yield of the light emitting element may be improved, and the color purity and brightness may be enhanced.

In a display device according to one or more embodiments, as a pixel electrode includes a groove, a contact area between the light emitting element and an adhesive layer is increased, thereby improving the bonding yield of the light emitting element.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in more detail example embodiments thereof with reference to the attached drawings, in which:

FIG. 1 is a perspective view illustrating a display device according to one or more embodiments;

FIGS. 2 and 3 are plan views illustrating a display device according to one or more embodiments;

FIG. 4 is a layout diagram showing the display area of FIG. 1 in more detail;

FIG. 5 is a cross-sectional view illustrating one or more embodiments of the display device taken along line I-I′ of FIG. 4;

FIG. 6 is a perspective view of a light emitting element according to one or more embodiments;

FIG. 7 is an enlarged cross-sectional view of the display device taken along line II-II′ of FIG. 6;

FIG. 8 is a perspective view of a light emitting element according to one or more embodiments;

FIG. 9 is an enlarged cross-sectional view of the display device taken along line III-III′ of FIG. 8;

FIG. 10 is an enlarged cross-sectional view of the display device taken along line IV-IV′ of FIG. 8;

FIGS. 11-12 are enlarged cross-sectional views of a display device according to one or more embodiments;

FIG. 13 is a cross-sectional view showing a bonding defect in a light emitting element that does not include a support portion;

FIG. 14 is a cross-sectional view schematically illustrating a display device according to one or more embodiments;

FIG. 15 is an enlarged view of area B of FIG. 14;

FIGS. 16-17 are enlarged views of area B according to one or more embodiments;

FIGS. 18-30 are diagrams illustrating a method of manufacturing a display device according to one or more embodiments;

FIG. 31 is an example diagram illustrating a virtual reality device including a display device according to one or more embodiments;

FIG. 32 is an example diagram illustrating a smart device including a display device according to one or more embodiments;

FIG. 33 is an example diagram illustrating a portion of an automobile including a display device according to one or more embodiments; and

FIG. 34 is an example diagram illustrating a transparent display device including a display device according to one or more embodiments.

### DETAILED DESCRIPTION

The present disclosure will now be described more fully hereinafter with reference to the accompanying drawings, in which example embodiments of the present disclosure are shown. This present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate (e.g., without any intervening layers therebetween), or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Hereinafter, embodiments will be described with reference to the accompanying drawings.

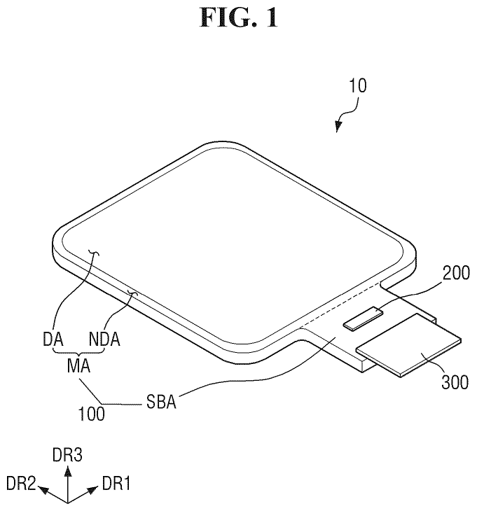

FIG. 1 is a perspective view illustrating a display device according to one or more embodiments.

Referring to FIG. 1, a display device 10 is a device for displaying a moving image and/or a still image. The display device 10 may be used as a display screen of one or more suitable devices, such as a television, a laptop computer, a monitor, a billboard and/or an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and/or an ultra-mobile PC (UMPC).

The display device 10 may be a light emitting display device such as an organic light emitting display using an organic light emitting diode, a quantum dot light emitting display including a quantum dot light emitting layer, an inorganic light emitting display including an inorganic semiconductor, and a micro light emitting display utilizing a micro or nano light emitting diode (LED). In the following description, a micro light emitting display device is exemplified as the display device 10, but the present disclosure is not limited thereto. For simplicity of description, an ultra-small light emitting diode is referred to hereafter as a micro light emitting diode.

The display device 10 includes a display panel 100, a display driving circuit 200, and a circuit board 300.

The display panel 100 may, in a plan view, be formed in a rectangular shape having short sides in a first direction DR1 and long sides in a second direction DR2 crossing the first direction DR1. The corner where the short side in the first direction DR1 and the long side in the second direction DR2 meet may be rounded to have a set or predetermined curvature or may be right-angled (e.g., may be a sharp right-angle corner). The planar shape of the display panel 100 is not limited to the rectangular shape, and may be formed in another suitable shape such as a polygonal shape, a circular shape and/or an elliptical shape. The display panel 100 may be formed to be flat (or substantially flat), but is not limited thereto. For example, the display panel 100 may include a curved portion formed at left and right ends (or edges) (e.g., may be curved at left and right ends (or edges), and the curved portion may have a constant curvature or a suitably varying curvature. In some embodiments, the display panel 100 may be formed flexibly so that it can be curved, bent, folded, and/or rolled.

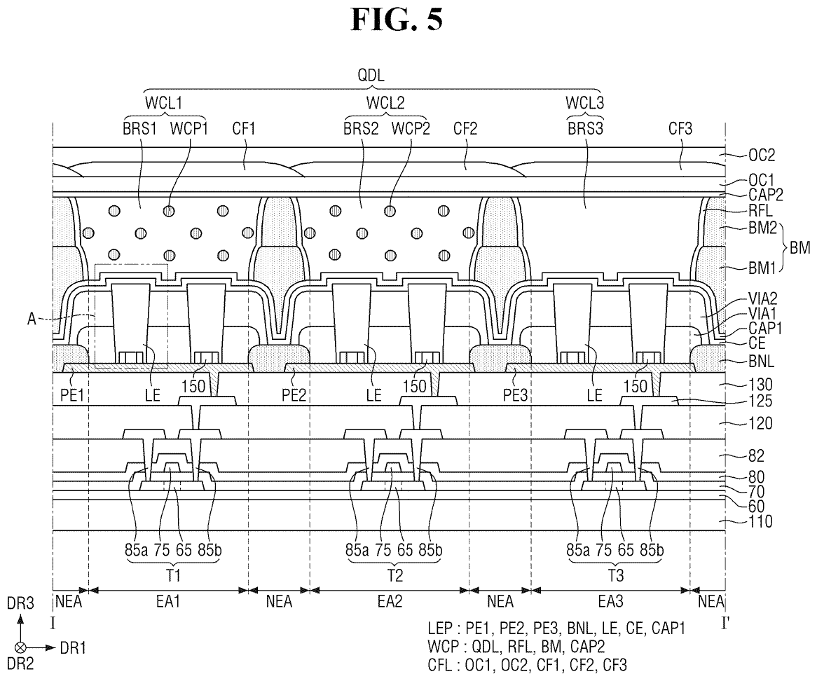

A substrate 110 (see FIG. 5) of the display panel 100 may include a main region MA and a sub-region SBA.

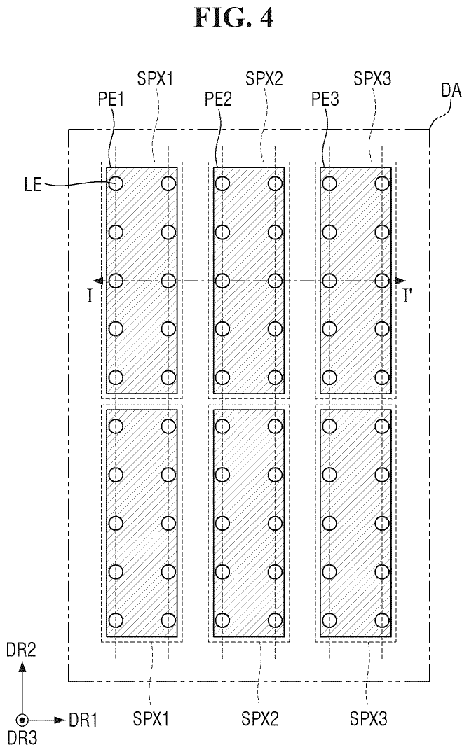

The main region MA may include a display area DA displaying (e.g., configured to display) an image and a non-display area NDA that is a peripheral area of the display area DA. The display area DA may include a plurality of pixels displaying (e.g., configured to display) an image. For example, the pixel may include a first sub-pixel SPX1 (see FIG. 4) emitting (e.g., configured to emit) first light, a second sub-pixel SPX2 (see FIG. 4) emitting (e.g., configured to emit) second light, and a third sub-pixel SPX3 (see FIG. 4) emitting (e.g., configured to emit) third light.

The sub-region SBA may protrude from one side of the main region MA in the second direction DR2. Although it is shown in FIG. 1 that the sub-region SBA is unfolded, in some embodiments, the sub-region SBA may be bent and, in this case, may be arranged on the bottom surface of the display panel 100. In the case where the sub-region SBA is bent, it may overlap the main region MA in a third direction DR3 that is a thickness direction of the display panel 100. The display driving circuit 200 may be arranged in the sub-region SBA.

The display driving circuit 200 may generate signals and voltages for driving the display panel 100. The display driving circuit 200 may be formed as an integrated circuit (IC) and attached onto the display panel 100 by a chip on glass (COG) method, a chip on plastic (COP) method, and/or an ultrasonic bonding method, but the present disclosure is not limited thereto. For example, the display driving circuit 200 may be attached onto the circuit board 300 by a chip on film (COF) method.

The circuit board 300 may be attached to one end of the sub-region SBA of the display panel 100. Thus, the circuit board 300 may be electrically connected to the display panel 100 and the display driving circuit 200. The display panel 100 and the display driving circuit 200 may receive digital video data, timing signals, and/or driving voltages through the circuit board 300. The circuit board 300 may be a flexible printed circuit board, a printed circuit board, and/or a flexible film such as a chip on film.

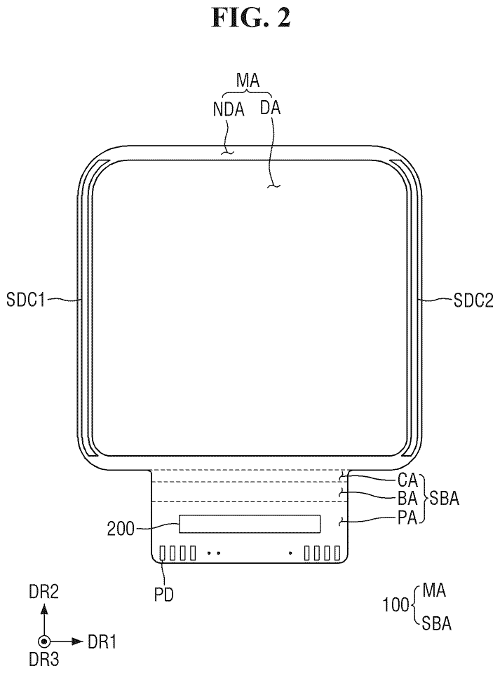

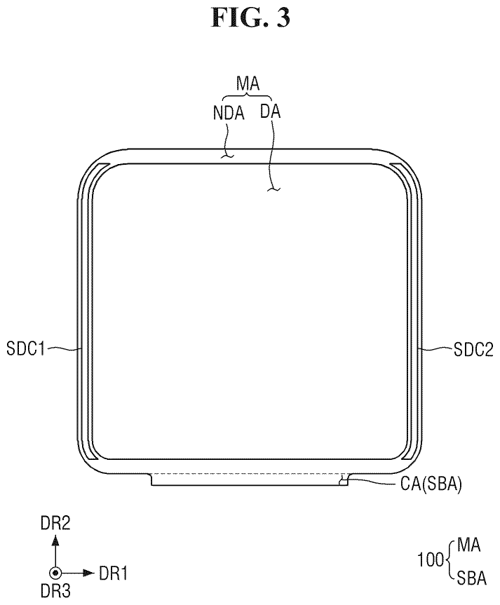

FIGS. 2 and 3 are plan views illustrating a display device according to one or more embodiments. It is exemplarily shown in FIG. 2 that the sub-region SBA is unfolded without being bent. It is exemplarily shown in FIG. 3 that the sub-region SBA is bent.

Referring to FIGS. 2 and 3, the display panel 100 may include the main region MA and the sub-region SBA.

The main region MA may include the display area DA displaying (e.g., configured to display) an image and the non-display area NDA that is a peripheral area of the display area DA. The display area DA may occupy most of the main region MA. The display area DA may be provided at the center (e.g., in the central portion) of the main region MA.

The non-display area NDA may be provided adjacent to the display area DA. The non-display area NDA may be an area outside the display area DA. The non-display area NDA may be provided to surround the display area DA. The non-display area NDA may be an edge area of the display panel 100.

A first scan driver SDC1 and a second scan driver SDC2 may be provided in the non-display area NDA. The first scan driver SDC1 may be provided at one side (for example, left side) of the display panel 100, and the second scan driver SDC2 may be provided at the other side (for example, right side) of the display panel 100, but the present disclosure is not limited thereto. Each of the first scan driver SDC1 and the second scan driver SDC2 may be electrically connected (e.g., electrically coupled) to the display driving circuit 200 through scan fan-out lines. Each of the first scan driver SDC1 and the second scan driver SDC2 may receive scan control signals inputted from the display driving circuit 200, generate scan signals in response to the scan control signals, and output the generated scan signals to scan lines.

The sub-region SBA may protrude from one side of the main region MA in the second direction DR2. The length of the sub-region SBA in the second direction DR2 may be less than the length of the main region MA in the second direction DR2. The length of the sub-region SBA in the first direction DR1 may be substantially equal to or less than the length of the main region MA in the first direction DR1. The sub-region SBA may be foldable to be provided under the display panel 100. In some embodiments, when bent or folded, the sub-region SBA may overlap the main region MA in a third direction DR3.

The sub-region SBA may include a connection area CA, a pad area PA, and a bending area BA.

The connection area CA is an area protruding from one side of the main region MA in the second direction DR2. One side of the connection area CA may be in contact with the non-display area NDA of the main region MA, and the other side of the connection area CA may be in contact with the bending area BA.

The pad area PA is an area in which pads PD and the display driving circuit 200 are provided. The display driving circuit 200 may be attached to driving pads of the pad area PA utilizing a conductive adhesive member such as an anisotropic conductive film. The circuit board 300 may be attached to the pads PD of the pad area PA utilizing a conductive adhesive member such as an anisotropic conductive film. One side of the pad area PA may be in contact with the bending area BA.

The bending area BA is an area being bent (e.g., configured to be bent). When the bending area BA is bent, the pad area PA may be provided under the connection area CA and the main region MA. The bending area BA may be provided between the connection area CA and the pad area PA. One side of the bending area BA may be in contact with the connection area CA, and the other side of the bending area BA may be in contact with the pad area PA.

FIG. 4 is a layout diagram showing the display area DA of FIG. 1 in more detail.

Referring to FIG. 4, the display area DA may include a plurality of pixels PX. Each of the plurality of pixels PX may include a first sub-pixel SPX1, a second sub-pixel SPX2, and a third sub-pixel SPX3.

The plurality of pixels PX may be arranged in a matrix form. In each of the pixels PX, the first sub-pixel SPX1, the second sub-pixel SPX2, and the third sub-pixel SPX3 may be alternately arranged with each other in the first direction DR1. The first sub-pixels SPX1 may be arranged in the second direction DR2, the second sub-pixels SPX2 may be arranged in the second direction DR2, and the third sub-pixels SPX3 may be arranged in the second direction DR2.

The first sub-pixel SPX1, the second sub-pixel SPX2, and the third sub-pixel SPX3 may include pixel electrodes PE1, PE2, and PE3, and a plurality of light emitting elements LE, respectively.

The pixel electrodes PE1, PE2, and PE3 may have a rectangular shape with a short side extending in the first direction DR1 and a long side extending in the second direction DR2 in a plan view, but the embodiments of the present disclosure are not limited thereto.

The plurality of light emitting elements LE may emit light in a blue wavelength band. The blue wavelength band may be in a range of approximately 370 nm to 460 nm, but embodiments of the present specification are not limited thereto.

The plurality of light emitting elements LE may be arranged to overlap the pixel electrodes PE1, PE2, and PE3. The plurality of light emitting elements LE may be spaced apart from each other in the first direction DR1 and the second direction DR2. The light emitting elements LE may be provided to be aligned in the first direction DR1, and may be provided to be aligned in the second direction DR2.

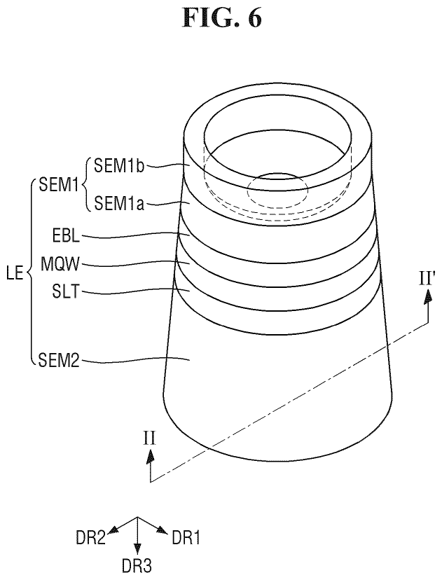

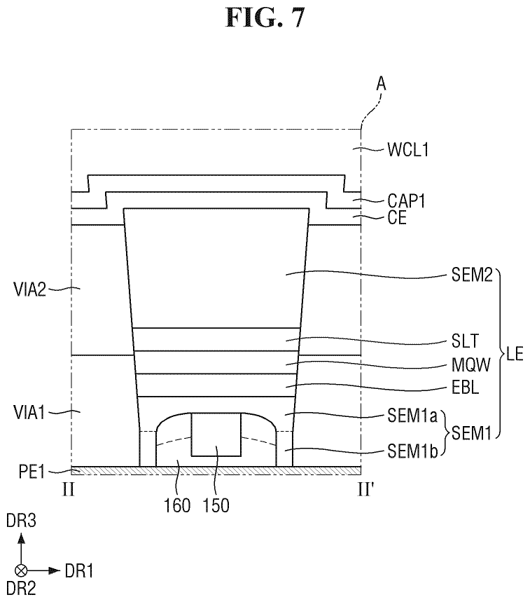

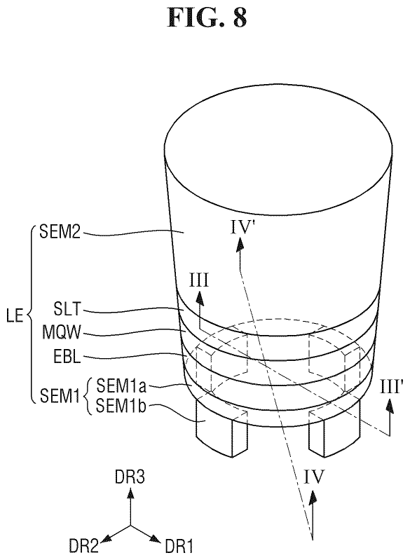

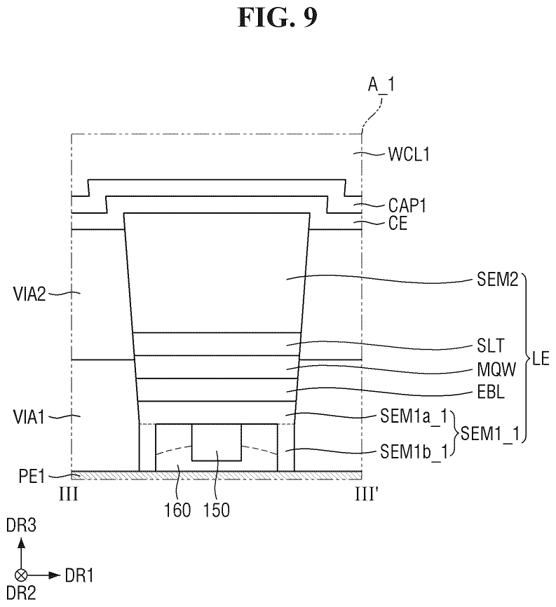

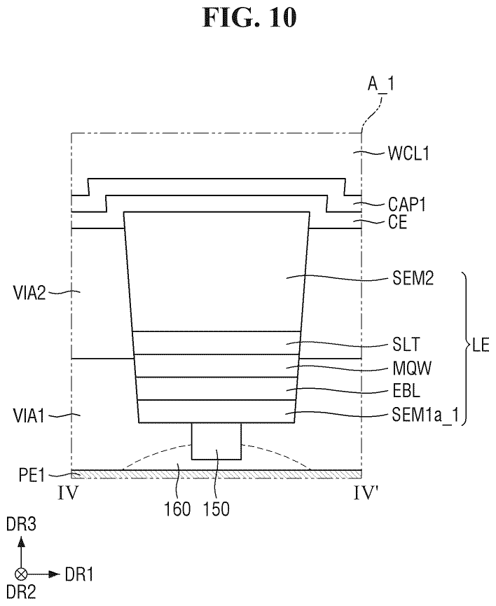

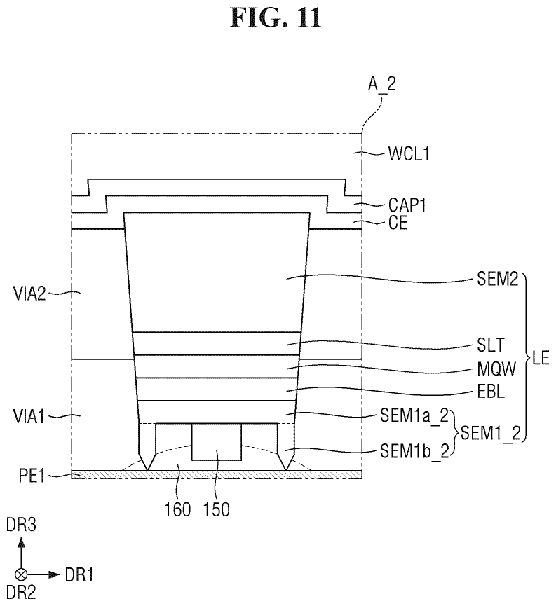

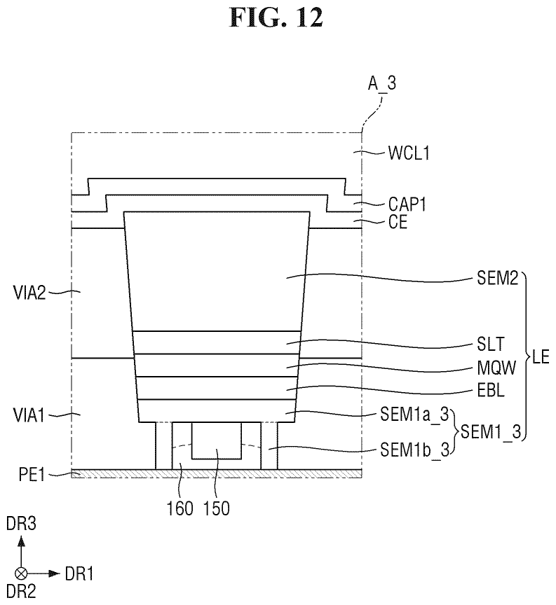

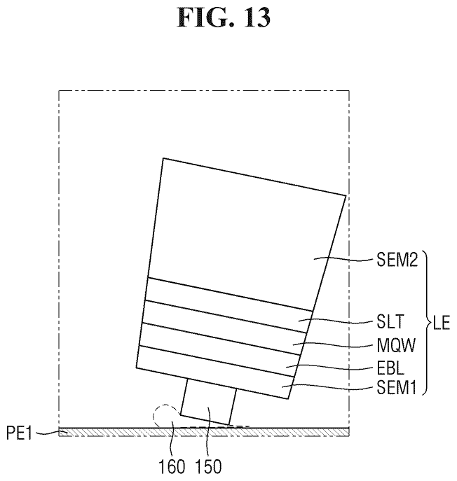

FIG. 5 is a cross-sectional view illustrating an embodiment of the display device taken along line I-I′ of FIG. 4. FIG. 6 is a perspective view of a light emitting element according to one or more embodiments. FIG. 7 is an enlarged cross-sectional view of area A of FIG. 5 and is also an enlarged cross-sectional view of the display device taken along line II-II′ of FIG. 6. FIG. 8 is a perspective view of a light emitting element according to one or more other embodiments. FIG. 9 is an enlarged cross-sectional view of the display device taken along line III-III′ of FIG. 8. FIG. 10 is an enlarged cross-sectional view of the display device taken along line IV-IV′ of FIG. 8. FIGS. 11 and 12 are enlarged cross-sectional views of a display device according to one or more other embodiments. FIG. 13 is a cross-sectional view showing a bonding defect in a light emitting element that does not include a support portion. In FIGS. 6 to 13, the same or similar reference numbers indicate the same or similar components.

Referring to FIG. 5, the display device 10 may include the substrate 110 and a light emitting element portion LEP provided on the substrate 110. The substrate 110 may be an insulating substrate. The substrate 110 may include a transparent material. For example, the substrate 110 may include a transparent insulating material such as glass, quartz, and/or the like. The substrate 110 may be a rigid substrate. However, the substrate 110 is not limited thereto. The substrate 110 may include plastic such as polyimide and/or the like, and may have a flexible property such that it can be twisted, bent, folded, and/or rolled. A plurality of emission areas EA1, EA2, and EA3 and a non-emission area NEA may be defined in the substrate 110.

Switching elements T1, T2, and T3 may be positioned on the substrate 110. In one or more embodiments, the first switching element T1 may be positioned in the first emission area EA1 of the substrate 110, the second switching element T2 may be positioned in the second emission area EA2 thereof, and the third switching element T3 may be positioned in the third emission area EA3 thereof. However, the present disclosure is not limited thereto, and in some embodiments, at least one of the first switching element T1, the second switching element T2, and the third switching element T3 may be located in the non-emission area NEA.

In one or more embodiments, each of the first switching element T1, the second switching element T2, and the third switching element T3 may be a thin film transistor including amorphous silicon, polysilicon, and/or an oxide semiconductor. In some embodiments, a plurality of signal lines (e.g., a gate line, a data line, a power line, and/or the like) that transmit signals to the switching elements may be further positioned on the substrate 110.

Each of the switching elements T1, T2, and T3 may include a semiconductor layer 65, a gate electrode 75, a source electrode 85a, and a drain electrode 85b.

For example, a buffer layer 60 may be provided on the substrate 110. The buffer layer 60 may be provided to cover the entire surface of the substrate 110. The buffer layer 60 may include silicon nitride, silicon oxide, and/or silicon oxynitride, and may be formed as a single layer or a double layer thereof (e.g., a double layer including any of the above materials).

The semiconductor layer 65 may be provided on the buffer layer 60. The semiconductor layer 65 may form a channel of each of the switching elements T1, T2, and T3, respectively. The semiconductor layer 65 may include amorphous silicon, polycrystalline silicon, and/or an oxide semiconductor. The oxide semiconductor may include, for example, a binary compound (Abₓ), a ternary compound (AbₓC_{y}), and/or a quaternary compound (AbₓC_{y}D_{z}) including indium, zinc, gallium, tin, titanium, aluminum, hafnium (Hf), zirconium (Zr), magnesium (Mg) and/or the like. In one or more embodiments, the semiconductor layer 65 may include indium tin zinc oxide (IGZO).

A gate insulating layer 70 may be provided on the semiconductor layer 65. The gate insulating layer 70 may include a silicon compound, a metal oxide, and/or the like. For example, the gate insulating layer 70 may include silicon oxide, silicon nitride, silicon oxynitride, aluminum oxide, tantalum oxide, hafnium oxide, zirconium oxide, titanium oxide, and/or the like. In one or more embodiments, the gate insulating layer 70 may include silicon oxide.

The gate electrode 75 may be provided on the gate insulating layer 70. The gate electrode 75 may be provided to overlap the semiconductor layer 65. The gate electrode 75 may include a conductive material. The gate electrode 75 may include a metal oxide such as ITO, IZO, ITZO, and/or In₂O₃, and/or a metal such as copper (Cu), titanium (Ti), aluminum (Al), molybdenum (Mo), tantalum (Ta), calcium (Ca), chromium (Cr), magnesium (Mg), and/or nickel (Ni). For example, the gate electrode 75 may be formed as a Cu/Ti double layer in which an upper layer made of copper is stacked on a lower layer made of titanium, but the present disclosure is not limited thereto.

A first interlayer insulating layer 80 and a second interlayer insulating layer 82 may be provided on the gate electrode 75. The first interlayer insulating layer 80 may be provided directly on the gate electrode 75, and the second interlayer insulating layer 82 may be provided directly on the first interlayer insulating layer 80. Each of the first interlayer insulating layer 80 and the second interlayer insulating layer 82 may include an inorganic insulating material such as silicon oxide, silicon nitride, silicon oxynitride, hafnium oxide, aluminum oxide, titanium oxide, tantalum oxide, zinc oxide, and/or the like. However, the present disclosure is not limited thereto, and the second interlayer insulating layer 82 may include an organic insulating material capable of flattening (or substantially flattening) a stepped portion provided thereunder. Although two interlayer insulating layers of the first interlayer insulating layer 80 and the second interlayer insulating layer 82 have been illustrated and described in the present embodiments, the present disclosure is not limited thereto, and only one interlayer insulating layer may also be provided.

The source electrode 85a and the drain electrode 85b may be provided on the second interlayer insulating layer 82. The source electrode 85a and the drain electrode 85b may be in contact with the semiconductor layer 65 through respective contact holes penetrating the first interlayer insulating layer 80, the second interlayer insulating layer 82, and the gate insulating layer 70. The source electrode 85a and the drain electrode 85b may include a metal oxide such as ITO, IZO, ITZO, and/or In₂O₃, and/or a metal such as copper (Cu), titanium (Ti), aluminum (Al), molybdenum (Mo), tantalum (Ta), calcium (Ca), chromium (Cr), magnesium (Mg), and/or nickel (Ni). For example, the source electrode 85a and the drain electrode 85b may be formed as a Cu/Ti double layer in which an upper layer made of copper is stacked on a lower layer made of titanium, but the present disclosure is not limited thereto.

A first planarization layer 120 may be provided on the first switching element T1, the second switching element T2, and the third switching element T3. The first planarization layer 120 may include an organic material. For example, the first planarization layer 120 may include acrylic resin, epoxy resin, imide resin, ester resin, and/or the like. In one or more embodiments, the first planarization layer 120 may include a positive photosensitive material and/or a negative photosensitive material.

A pixel connection electrode 125 may be provided on the first planarization layer 120. The pixel connection electrode 125 may be provided to correspond to each of the first switching element T1, the second switching element T2, and the third switching element T3, and may be electrically connected thereto. The pixel connection electrode 125 may connect pixel electrodes PE1, PE2, and PE3 to be described in more detail herein below to the above-described switching elements T1, T2, and T3, respectively. The pixel connection electrode 125 may be in contact with the switching elements T1, T2, and T3 through respective contact holes penetrating the first planarization layer 120.

A second planarization layer 130 may be provided on the first planarization layer 120 and the pixel connection electrode 125. The second planarization layer 130 may flatten (or substantially flatten) a stepped portion provided thereunder, and may include the same material as that of the above-described first planarization layer 120.

The light emitting element portion LEP may be provided on the second planarization layer 130. The light emitting element portion LEP may include the plurality of pixel electrodes PE1, PE2, and PE3, the plurality of light emitting elements LE, and the common electrode CE. In addition, the light emitting element portion LEP may further include a bank layer BNL that partitions the emission areas EA1, EA2, and EA3, and a first via layer VIA1 and a second via layer VIA2.

The plurality of pixel electrodes PE1, PE2, and PE3 may include the first pixel electrode PE1, the second pixel electrode PE2, and the third pixel electrode PE3. The first pixel electrode PE1, the second pixel electrode PE2, and the third pixel electrode PE3 may serve as the first electrode of the respective light emitting element LE, and may be an anode electrode or a cathode electrode. The first pixel electrode PE1 may be located in the first emission area EA1, the second pixel electrode PE2 may be located in the second emission area EA2, and the third pixel electrode PE3 may be located in the third emission area EA3. In some embodiments, the first pixel electrode PE1 may overlap the first emission area EA1, the second pixel electrode PE2 may overlap the second emission area EA2, and the third pixel electrode PE3 may overlap the third emission area EA3.

The pixel electrodes PE1, PE2, and PE3 may be directly connected to the pixel connection electrode 125 through the respective contact holes penetrating the second planarization layer 130, and may be electrically connected to the switching elements T1, T2, and T3 through the pixel connection electrode 125, respectively. The first pixel electrode PE1, the second pixel electrode PE2, and the third pixel electrode PE3 may include glass and/or metal. The metal may include, e.g., copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. Further, the first pixel electrode PE1, the second pixel electrode PE2, and the third pixel electrode PE3 may have a multi-layer structure in which two or more metal layers are stacked. For example, the first pixel electrode PE1, the second pixel electrode PE2, and the third pixel electrode PE3 may have a two-layer structure in which a copper layer is stacked on a titanium layer, but the present disclosure is not limited thereto.

In one or more embodiments, the pixel electrodes PE1, PE2, and PE3 may be glass. When the pixel electrodes PE1, PE2, and PE3 are made of glass, they may be easily or suitably bonded with a light emitting element LE including a support.

The bank layer BNL may be arranged to cover the edges of the pixel electrodes PE1, PE2, and PE3. The bank layer BNL may be formed of an organic layer such as acryl resin, epoxy resin, phenolic resin, polyamide resin, polyimide resin and/or the like. The bank layer BNL may include a light blocking material to prevent or reduce the traveling of light of the light emitting element LE of any one sub-pixel to the neighboring sub-pixel. For example, the bank layer BNL may contain an organic black pigment and/or an inorganic black pigment such as carbon black and/or the like.

The light emitting element LE may be provided on the pixel electrodes PE1, PE2, and PE3 that are exposed without being covered by the bank layer BNL. One or more light emitting elements LE may be provided on each of the pixel electrodes PE1, PE2, and PE3.

As illustrated in FIG. 5, the light emitting elements LE may be provided in each of the first emission area EA1, the second emission area EA2, and the third emission area EA3, respectively. The light emitting element LE may be a vertical light emitting diode element elongated in the third direction DR3. For example, the length of the light emitting element LE in the third direction DR3 may be longer than the length thereof in the horizontal direction. The length in the horizontal direction refers to a length in the first direction DR1 or a length in the second direction DR2. For example, the length of the light emitting element LE in the third direction DR3 may be approximately 1 μm to 5 μm. However, the present disclosure is not limited thereto, and the length of the light emitting element LE in the third direction DR3 may also be equal to or smaller than the length thereof in the horizontal direction.

The light emitting element LE may be a micro light emitting diode element. Referring to FIGS. 6 and 7, a connection electrode 150 and an adhesive layer 160 may be provided between the light emitting element LE and the respective pixel electrodes PE1, PE2, and PE3. The light emitting element LE may include a first semiconductor layer SEM1, an electron blocking layer EBL, an active layer MQW, a superlattice layer SLT, and a second semiconductor layer SEM2 that are sequentially stacked in the thickness direction of the substrate 110 that is the third direction DR3. The light emitting element LE may include an insulating layer surrounding (e.g., around) at least a part of the first semiconductor layer SEM1, the active layer MQW, and the second semiconductor layer SEM2.

The light emitting element LE may have a cylindrical shape, a disk shape, and/or a rod shape that is longer in height than in width. However, the present disclosure is not limited thereto, and the light emitting element LE may have one or more suitable shapes, such as a rod shape, a wire shape, a tube shape, a polygonal prism shape (such as a regular cube, a rectangular parallelepiped and/or a hexagonal prism), and/or a shape extending in one direction and having a partially inclined outer surface.

The first semiconductor layer SEM1 may be provided on the pixel electrodes PE1, PE2, and PE3 and the connection electrode 150. The first semiconductor layer SEM1 may include a body portion SEM1a that is provided adjacent to the active layer MQW and/or the electron blocking layer EBL, and a support portion SEM1b that protrudes from the body portion SEM1a toward the pixel electrodes PE1, PE2, and PE3. The body portion SEM1a may cover the entire contact surface of the upper electron blocking layer EBL and/or active layer MQW that is in contact therewith.

The support portion SEM1b may be provided on the edge of the body portion SEM1a or may be provided adjacent to the edge thereof. The support portion SEM1b may be in contact with the pixel electrodes PE1, PE2, and PE3 to support the light emitting element LE so that the light emitting element LE may stand in a suitably stable state without falling over on the pixel electrodes PE1, PE2, and PE3.

The body portion SEM1a and the support portion SEM1b of the first semiconductor layer SEM1 may be one body (e.g., may together form one integral body) and may include the same material. After forming the first semiconductor layer SEM1, a part thereof may be etched to form the support portion SEM1b. The first semiconductor layer SEM1 may be a p-type semiconductor, and may include a semiconductor material having a chemical formula of AlₓGa_{y}In_{1-x-y}N (0≤x≤1, 0≤y≤1, 0≤x+y≤1). For example, it may be any one or more of p-type doped AlGalnN, GaN, AlGaN, InGaN, AlN and InN. The first semiconductor layer SEM1 may be doped with a p-type dopant, and the p-type dopant may be Mg, Zn, Ca, Ba, and/or the like. For example, the first semiconductor layer SEM1 may be p-GaN doped with p-type Mg. The total thickness of the first semiconductor layer SEM1 may be in a range of 30 nm to 200 nm, but is not limited thereto.

The connection electrode 150 may be provided on the respective pixel electrodes PE1, PE2, and PE3, and may be provided between the light emitting element LE and the respective pixel electrodes PE1, PE2, and PE3. For example, the connection electrode 150 may be provided on the bottom surface of the body portion SEM1a of the first semiconductor layer SEM1 of the light emitting element LE. The support portion SEM1b of the first semiconductor layer SEM1 may have a thickness equal to or greater than the thickness of the connection electrode 150. In one or more embodiments, the connection electrode 150 may be in contact with the pixel electrodes PE1, PE2, and PE3. In some embodiments, the connection electrode 150 may be in contact with the adhesive layer 160 without being in contact with the pixel electrodes PE1, PE2, and PE3.

When the light emitting element LE is electrically connected to the pixel electrode in the display panel 100 according to one or more embodiments, the connection electrode 150 may reduce resistance between the light emitting element LE and the pixel electrode. The connection electrode 150 may include a conductive metal. For example, the connection electrode 150 may include at least one of gold (Au), copper (Cu), tin (Sn), titanium (Ti), aluminum (Al), and silver (Ag). For example, the connection electrode 150 may contain a 9:1 alloy, a 8:2 alloy and/or a 7:3 alloy of gold and tin, and/or may contain an alloy (SAC305) of copper, silver, and tin.

In some embodiments, an ohmic contact layer may be further provided on the connection electrode 150. The ohmic contact layer may be provided between the connection electrode 150 and the first semiconductor layer SEM1. The ohmic contact layer may be an ohmic connection electrode. However, the present disclosure is not limited thereto, and it may be a Schottky connection electrode. The ohmic contact layer may include ITO. However, it is not limited thereto, and may include at least one selected from among gold (Au), copper (Cu), tin (Sn), titanium (Ti), aluminum (Al), and silver (Ag), an alloy, and/or a multi-layer structure thereof.

The adhesive layer 160 may be provided between the connection electrode 150 and the respective pixel electrodes PE1, PE2, and PE3 to physically and electrically connect them to each other. The adhesive layer 160 may include a conductive material. In one or more embodiments, the adhesive layer 160 may include an anisotropic conductive film and/or a solder. The solder may be at least one of, or an alloy of two or more of, gold (Au), copper (Cu), tin (Sn), titanium (Ti), aluminum (Al), and silver (Ag). Herein, the case where the adhesive layer 160 is solder is exemplified. However, this is only an example, and the present disclosure is not limited thereto. For example, the adhesive layer 160 may include an alloy (SAC305) of copper, silver, and tin.

The connection electrode 150 may be melt-bonded to the pixel electrodes PE1, PE2, and PE3 through a soldering process of the adhesive layer 160. Because the adhesive layer 160 is melted by a laser and/or heat and pressure, it may have a spread form. Additionally, after melting, it may be difficult to clearly or suitably distinguish the boundary line between the adhesive layer 160 and the connection electrode 150. However, because the adhesive layer 160 and the first semiconductor layer SEM1 of the light emitting element LE include different materials, they may be distinguished from each other even after melting.

The adhesive layer 160 and the connection electrode 150 may overlap the support portion SEM1b of the first semiconductor layer SEM1 in the horizontal direction of the substrate (e.g., the first direction DR1). The support portion SEM1b of the first semiconductor layer SEM1 may be provided adjacent to the edge (e.g., the peripheral circumference) of the body portion SEM1a. The adhesive layer 160 and the connection electrode 150 may be provided adjacent to the center of the body portion SEM1a compared to (e.g., relative to) the support portion SEM1b. The adhesive layer 160 may be sealed by the support portion SEM1b of the first semiconductor layer SEM1, or a part of the adhesive layer 160 may escape from the support portion SEM1b and spread further from the support portion SEM1b. A part of the adhesive layer 160 may not overlap the body portion SEM1a of the first semiconductor layer SEM1 in the thickness direction of the substrate (the third direction DR3).

Referring to FIGS. 6 and 7, the support portion SEM1b may be provided on the edge (e.g., peripheral circumference) of the body portion SEM1a and may be shaped to surround the body portion SEM1a along the edge. The body portion SEM1a may include a curved bottom surface (see FIG. 7) that faces the pixel electrodes PE1, PE2, and PE3 in cross-sectional view. However, it is not limited thereto and may also have a flat (or substantially flat) bottom surface. The thickness of the support portion SEM1b surrounding the body portion SEM1a may be constant (or substantially constant).

The connection electrode 150 may be surrounded by the support portion SEM1b. The adhesive layer 160 may also be surrounded by the support portion SEM1b. However, when a part of the solder is pushed out of the support portion SEM1b during bonding of the light emitting element LE and the pixel electrodes PE1, PE2, and PE3, a part of the adhesive layer 160 (e.g., the part that was pushed out) may not be surrounded by the support portion SEM1b.

In FIGS. 6 and 7, the lower space of the body portion SEM1a of the first semiconductor layer SEM1 may be surrounded by the support portion SEM1b and the pixel electrodes PE1, PE2, and PE3, and the connection electrode 150 and the adhesive layer 160 may only be located therein. The space between the body portion SEM1a of the first semiconductor layer SEM1 and the adhesive layer 160 may be empty.

Referring to FIGS. 8 to 10, the support portion SEM1b may include a first pillar and a second pillar facing each other. The first pillar and the second pillar may be spaced apart from each other in a plan view. The thickness of the first pillar may be the same as the thickness of the second pillar.

Referring to FIG. 9, the adhesive layer 160 and the connection electrode 150 may be provided between the first pillar and the second pillar. Referring to FIG. 10, in the separation space between the first pillar and the second pillar (line IV-IV′ of FIG. 8), because the support portion does not exist between a body portion SEM1a_1 and the respective pixel electrodes PE1, PE2, and PE3, the adhesive layer 160 may spread widely. For example, the width of the adhesive layer 160 in the separation space between the first pillar and the second pillar may be larger than the distance between the first pillar and the second pillar.

As shown in FIG. 8, when the support portion SEM1b is configured with a plurality of pillars, the lower space of the body portion SEM1a of the first semiconductor layer SEM1 includes an open portion which is not laterally blocked or surrounded by the support portion SEM1b. The space between the adhesive layer 160 and the body portion SEM1a of the first semiconductor layer SEM1 may be empty, or a via layer, which will be described in more detail herein below, may be provided therein.

FIG. 11 is a cross-sectional view of the light emitting element LE according to one or more embodiments. The light emitting element LE of FIG. 11 is different from the light emitting element LE of FIG. 9 in that a cross section of a support portion SEM1b_2 is pentagonal. Here, a part of the adhesive layer 160 may spread further from the support portion SEM1b_2. The support portion SEM1b of the first semiconductor layer SEM1 may have any suitable shape as long as it can suitably support the light emitting element LE on the respective pixel electrodes PE1, PE2, and PE3. In an example embodiment, the cross-sectional shape of the support portion SEM1b may be a polygonal shape, such as a square, pentagonal, and/or hexagonal shape.

FIG. 12 is a cross-sectional view of the light emitting element LE according to one or more embodiments. Compared to FIG. 9, a support portion SEM1b_3 of the first semiconductor layer SEM1_3 of FIG. 12 may be located inside an edge (e.g., inside a peripheral circumference) of a body portion SEM1a_3 without being aligned with the edge thereof. By adjusting an etching process for forming the support portion SEM1b of the first semiconductor layer SEM1, the position of the support portion SEM1b may be adjusted.

As shown in FIG. 13, in a case where the light emitting element LE does not include a support portion at the lower portion thereof, if the material of the adhesive layer 160 is not suitably aligned at the center of the light emitting element LE, the light emitting element LE may not be suitably attached to the pixel electrodes PE1, PE2, and PE3 and may fall over. Or, for example, the light emitting element LE may be tilted and bonded to the pixel electrodes PE1, PE2, and PE3 in this tilted arrangement, thereby reducing the light emission efficiency. When solder is used as the material of the adhesive layer 160, it may be difficult to finely or suitably control the size and position of the solder. Therefore, the light emitting element LE may often fall over or tilt.

As illustrated in FIGS. 5 to 12, in embodiments where the light emitting element LE includes the support portion SEM1b, even if the alignment of the material of the adhesive layer 160 is biased to one side or the material of the adhesive layer 160 is partially melted, the support portion SEM1b may allow the light emitting element LE to stably or suitably stand on the pixel electrodes PE1, PE2, and PE3. The support portion SEM1b may prevent or reduce the far spreading of the material of the adhesive layer 160, and thus may allow the material to concentrate on connecting the connection electrode 150 to the pixel electrodes PE1, PE2, and PE3. Additionally, the adhesive layer 160 may be in contact with the support portion SEM1b, in addition to the body portion SEM1a, thereby increasing the contact area and improving the adhesion. Accordingly, the bonding yield of the light emitting element LE may be improved, and the color purity and brightness of the display panel may be enhanced.

Referring to FIGS. 5 and 6, the electron blocking layer EBL may be provided on the first semiconductor layer SEM1. The electron blocking layer EBL may be a layer for suppressing or reducing too many electrons from flowing into the active layer MQW. For example, the electron blocking layer EBL may be AlGaN and/or p-AlGaN doped with p-type Mg. In some embodiments, the electron blocking layer EBL may not be provided (e.g., may be omitted).

The active layer MQW may be provided on the electron blocking layer EBL. The active layer MQW may emit light by recombining of electron-hole pairs according to an electrical signal applied through the first semiconductor layer SEM1 and the second semiconductor layer SEM2. The active layer MQW may emit first light having a central wavelength band of 450 nm to 495 nm, e.g., light of a blue wavelength band.

The active layer MQW may include a material having a single or multiple quantum well structure. When the active layer MQW contains a material having a multiple quantum well structure, the active layer MQW may have the structure in which a plurality of well layers and barrier layers are alternately stacked. For example, the well layer may be formed of InGaN, and the barrier layer may be formed of GaN and/or AlGaN, but the present disclosure is not limited thereto. The thickness of the well layer may be approximately 1 to 4 nm, and the thickness of the barrier layer may be 3 nm to 10 nm.

In some embodiments, the active layer MQW may have a structure in which semiconductor materials having a relatively large band gap energy and semiconductor materials having a relatively small band gap energy are alternately stacked, and may include other suitable group III to V semiconductor materials according to the wavelength band of the emitted light. The light emitted by the active layer MQW is not limited to the first light, and in some embodiments, second light (e.g., light of the green wavelength band) and/or third light (e.g., light of the red wavelength band) may be emitted. In some embodiments, when the semiconductor material(s) included in the active layer MQW include indium, the color of emitted light may vary depending on the content (e.g., amount) of indium. For example, when the content of indium is about 15%, light of the blue wavelength band may be emitted, when the content of indium is about 25%, light of the green wavelength band may be emitted, and when the content of indium is about 35% or more, light of the red wavelength band may be emitted. The superlattice layer SLT may be provided on the active layer MQW. The superlattice layer SLT may be a layer for relieving or reducing stress between the second semiconductor layer SEM2 and the active layer MQW. For example, the superlattice layer SLT may be formed of InGaN and/or GaN. In some embodiments, the superlattice layer SLT may not be provided (e.g., may be omitted).

The second semiconductor layer SEM2 may be provided on the superlattice layer SLT. The second semiconductor layer SEM2 may be an n-type semiconductor. The second semiconductor layer SEM2 may include a semiconductor material having a chemical formula of AlₓGa_{y}In_{1-x-y}N (0≤x≤1, 0≤y≤1, 0≤x+y≤1). For example, the semiconductor material may be any one or more of n-type doped AlGalnN, GaN, AlGaN, InGaN, AlN and InN. The second semiconductor layer SEM2 may be doped with an n-type dopant, and the n-type dopant may be Si, Ge, Sn, Se, and/or the like. For example, the second semiconductor layer SEM2 may be n-GaN doped with n-type Si. The thickness of the second semiconductor layer SEM2 may be within a range of 2 μm to 4 μm, but the present disclosure is not limited thereto.

The first via layer VIA1 may be provided on the pixel electrodes PE1, PE2, and PE3 and the bank layer BNL. The height of the first via layer VIA1 may be smaller than the height of the light emitting element LE. The first via layer VIA1 may be provided to correspond to each of the emission areas EA1, EA2, and EA3. For example, the first via layer VIA1 may be provided in an island pattern shape in each of the emission areas EA1, EA2, and EA3. For example, the first via layer VIA1 provided in the emission areas EA1, EA2, and/or EA3 may be provided to be spaced apart from the first via layer VIA1 provided in the adjacent emission areas EA1, EA2, and/or EA3. A part of the first via layer VIA1 may be in contact with the bank layer BNL.

The first via layer VIA1 may include an organic material to flatten (or substantially flatten) the stepped portion provided thereunder. For example, the first via layer VIA1 may include acrylic resin, epoxy resin, phenolic resin, polyamide resin, polyimide resin, unsaturated polyester resin, polyphenylene resin, polyphenylenesulfide resin, benzocyclobutene (BCB), and/or the like.

The second via layer VIA2 may be provided on the bank layer BNL and the first via layer VIA1. The second via layer VIA2 may cover the first via layer VIA1 and flatten (or substantially flatten) the stepped portion provided thereunder so that the common electrode CE, which will be described in more detail herein below, may be formed. The second via layer VIA2 may include the same organic material as the first via layer VIA1. The second via layer VIA2 may be formed to have a set or predetermined height such that at least a part of the light emitting element LE, for example, the second semiconductor layer SEM2, may protrude above the second via layer VIA2. For example, the height of the second via layer VIA2 may be smaller than the height of the light emitting element LE.

The second via layer VIA2 may cover and protect the first via layer VIA1 provided in each of the emission areas EA1, EA2, and EA3. The second via layer VIA2 may be provided to correspond to each of the emission areas EA1, EA2, and EA3, respectively. For example, the second via layer VIA2 may be provided in an island pattern shape in each of the emission areas EA1, EA2, and EA3. For example, the second via layer VIA2 provided in the emission areas EA1, EA2, and/or EA3 may be provided to be spaced apart from the second via layer VIA2 provided in the adjacent emission areas EA1, EA2, and/or EA3.

The common electrode CE may be provided on the second via layer VIA2, the bank layer BNL, and the plurality of light emitting elements LE. For example, the common electrode CE may be provided on one surface of the substrate 110 on which the light emitting element LE is formed, and may be entirely provided in the display area DA of the substrate 110. The common electrode CE may be provided to overlap each of the emission areas EA1, EA2, and EA3 and the non-emission area NEA, and may be formed with a suitably thin thickness such that light may be suitably emitted. The common electrode CE may be directly provided on the top surface and

the side surface of the plurality of light emitting elements LE. The common electrode CE may be directly in contact with the second semiconductor layer SEM2 exposed on the top surface of the light emitting element LE. As illustrated in FIG. 5, the common electrode CE may be a common layer that covers the plurality of light emitting elements LE and is provided by commonly connecting the plurality of light emitting elements LE. Because the second semiconductor layer SEM2 having conductivity has a patterned structure in each of the light emitting elements LE, the common electrode CE may be directly in contact with the second semiconductor layer SEM2 of each of the light emitting elements LE so that a common voltage may be applied to each of the light emitting elements LE.

Because the common electrode CE is entirely provided on the substrate 110 and a common voltage is applied, the common electrode CE may include a material having a relatively low resistance. For example, the common electrode CE may include a metal material having a relatively low resistance, such as aluminum (Al), silver (Ag), copper (Cu), and/or the like, and/or a metal oxide such as ITO, IZO, ITZO, and/or the like. The thickness of the common electrode CE may be approximately 10 Å to 200 Å, but is not limited thereto.

The above-described light emitting elements LE may receive a pixel voltage or an anode voltage from each of the pixel electrodes PE1, PE2, and PE3, and may receive a common voltage through the common electrode CE. The light emitting elements LE may emit light with a set or predetermined luminance according to a voltage difference between the pixel voltage and the common voltage. In one or more embodiments, by disposing the plurality of light emitting elements LE, for example, inorganic light emitting diodes, on the pixel electrodes PE1, PE2, and PE3, the disadvantages of organic light emitting diodes, which are vulnerable to external moisture and/or oxygen, may be excluded or reduced, and lifespan and reliability may be improved.

The light emitting element portion LEP may further include a first capping layer CAP1 covering the common electrode CE. The first capping layer CAP1 may be directly provided on the common electrode CE. The first capping layer CAP1 serves to cover the elements provided thereunder, e.g., the light emitting elements LE and the common electrode CE, to protect them from moisture and/or foreign substances.

The first capping layer CAP1 may contain an inorganic material. For example, the first capping layer CAP1 may contain at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. The first capping layer CAP1 may be formed as a multilayer in which inorganic layers, each of which includes at least one of the aforementioned example materials that can be contained in the first capping layer CAP1, are alternately stacked.

A wavelength controller WCP may be provided on the light emitting element portion LEP. The wavelength controller WCP may include a wavelength conversion layer QDL, a reflective layer RFL, a light blocking portion BM including a first light blocking layer BM1 and a second light blocking layer BM2, and a second capping layer CAP2.

The light blocking portion BM may be provided on the first capping layer CAP1, and may partition the plurality of emission areas EA1, EA2, and EA3. The light blocking portion BM may be provided to extend in the first direction DR1 and the second direction DR2, and may be formed in a grid pattern in the entire display area DA. In some embodiments, the light blocking portion BM may not overlap the plurality of emission areas EA1, EA2, and EA3, and may overlap the non-emission area NEA.

The light blocking portion BM may serve to provide a space for forming the wavelength conversion layer QDL. To this end, the light blocking portion BM may include the first light blocking layer BM1 and the second light blocking layer BM2 provided on the first light blocking layer BM1. In order to provide a space for forming the wavelength conversion layer QDL, the light blocking portion BM may have a two-layer structure including the first light blocking layer BM1 and the second light blocking layer BM2 to have a relatively large or suitable thickness. For example, the thickness of the first light blocking layer BM1 and the thickness of the second light blocking layer BM2 may be within a range of 1 μm to 10 μm. The first light blocking layer BM1 and the second light blocking layer BM2 may include an organic insulating material to have a relatively large or suitable thickness. The organic insulating material may contain, for example, epoxy resin, acrylic resin, cardo resin, and/or imide resin.

In one or more embodiments, the first light blocking layer BM1 and the second light blocking layer BM2 may block or reduce transmission of light in the non-emission area NEA. The first light blocking layer BM1 and the second light blocking layer BM2 may further include a light blocking material, and may include a dye and/or pigment having a light blocking property. For example, the first light blocking layer BM1 and the second light blocking layer BM2 may be a black matrix. External light incident from the outside of the display device 10 may cause distortion of color reproducibility of the wavelength controller WCP. In accordance with the present embodiments, at least a part of the external light is absorbed by the light blocking portion BM by providing the light blocking portion BM including the light blocking material in the wavelength controller WCP. Accordingly, color distortion caused by the reflection of the external light may be reduced. Further, the light blocking portion BM including the light blocking material may prevent or reduce light infiltration and color mixture between adjacent emission areas, which leads to further improvement of color reproducibility. In the present embodiments, although the light blocking portion BM including the first light blocking layer BM1 and the second light blocking layer BM2 has been illustrated and described, the present disclosure is not limited thereto, and the light blocking portion BM may also be formed of a single layer.

The reflective layer RFL may be provided on the light blocking portion BM. The reflective layer RFL may not overlap the emission areas EA1, EA2, and EA3, and may be provided to overlap the non-emission area NEA. The reflective layer RFL may be provided to extend in the first direction DR1 and the second direction DR2, and may be formed in a grid pattern in the entire display area DA. The reflective layer RFL may entirely overlap the light blocking portion BM.

The reflective layer RFL may reflect light emitted from the light emitting elements LE upward (e.g., in the third direction DR3). The reflective layer RFL may include a metal material with a relatively high light reflectance, such as aluminum (Al).

In one or more embodiments, the wavelength conversion layer QDL may be provided on each of the emission areas EA1, EA2, and EA3. The wavelength conversion layer QDL may emit light by converting and/or shifting the peak wavelength of incident light to another set or specific peak wavelength. The wavelength conversion layer QDL may convert the first light that is blue light emitted from the light emitting element LE into the second light that is red light and/or into the third light that is green light, and/or may transmit the first light that is blue light without conversion.

The wavelength conversion layer QDL may be provided in each of the emission areas EA1, EA2, and EA3 partitioned by the light blocking portion BM, and may be provided to be spaced apart from each other. For example, the wavelength conversion layer QDL may include island patterns spaced apart from each other. The wavelength conversion layer QDL may be provided to overlap each of the first emission area EA1, the second emission area EA2, and the third emission area EA3. In an example embodiment, each of the wavelength conversion layers QDL may completely overlap the first emission area EA1, the second emission area EA2, and the third emission area EA3, respectively.

The wavelength conversion layer QDL may include a first wavelength conversion layer WCL1 overlapping the first emission area EA1, a second wavelength conversion layer WCL2 overlapping the second emission area EA2, and a light transmission layer WCL3 overlapping the third emission area EA3.

The first wavelength conversion layer WCL1 may be provided to overlap the first emission area EA1. The first wavelength conversion layer WCL1 may emit light by converting and/or shifting the peak wavelength of incident light to another set or specific peak wavelength. In one or more embodiments, the first wavelength conversion layer WCL1 may convert the first light that is blue light emitted from the light emitting element LE of the first emission area EA1 into the second light that is red light having a single peak wavelength in the range of about 610 nm to about 650 nm and emit the red light.

The first wavelength conversion layer WCL1 may include a first base resin BRS1 and a first wavelength conversion particle WCP1. In some embodiments, the first wavelength conversion layer WCL1 may further include a scatterer. The first base resin BRS1 may include a light-transmissive organic material. For example, the first base resin BRS1 may contain epoxy resin, acrylic resin, cardo resin, and/or imide resin.

The first wavelength conversion particle WCP1 may convert the first light incident from the light emitting element LE into second light. For example, the first wavelength conversion particle WCP1 may convert light in a blue wavelength band into light in a red wavelength band. The first wavelength conversion particle WCP1 may be a quantum dot (QD), a quantum rod, a fluorescent material, and/or a phosphorescent material. For example, a quantum dot may be a particulate material that emits (or is configured to emit) light of a set or specific color when an electron transitions from a conduction band to a valence band.

The quantum dot may be a semiconductor nanocrystal material. The quantum dot may have a set or specific band gap according to its composition and size. Thus, the quantum dot may absorb light and then emit light having an intrinsic (e.g., a set) wavelength. Examples of semiconductor nanocrystal of quantum dots may include group IV nanocrystal, group II-VI compound nanocrystal, group III-V compound nanocrystal, group IV-VI nanocrystal, a combination thereof, and/or the like.

The group II-VI compound may be at least one selected from the group consisting of binary compounds, ternary compounds, and quaternary compounds, wherein the binary compounds are selected from the group consisting of CdSe, CdTe, ZnS, ZnSe, ZnTe, ZnO, HgS, HgSe, HgTe, MgSe, MgS and mixtures thereof, the ternary compounds are selected from the group consisting of InZnP, AglnS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof, and the quaternary compounds are selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

The group III-V compound may be at least one selected from the group consisting of binary compounds, ternary compounds, and quaternary compounds, wherein the binary compounds are selected from the group consisting of GaN, GaP, GaAs, GaSb, AlN, AlP, AlAs, AlSb, InN, InP, InAs, InSb and mixtures thereof, the ternary compounds are selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb and mixtures thereof, and the quaternary compounds are selected from the group consisting of GaAlNP, GaAlNAs, GaAlNSb, GaAlPAs, GaAlPSb, GalnNP, GalnNAs, GalnNSb, GalnPAs, GalnPSb, InAlNP, InAlNAs, InAlNSb, InAlPAs, InAlPSb and mixtures thereof.

The group IV-VI compound may be at least one selected from the group consisting of binary compounds, ternary compounds, and quaternary compounds, wherein the binary compounds are selected from the group consisting of SnS, SnSe, SnTe, PbS, PbSe, PbTe and mixtures thereof, the ternary compounds are selected from the group consisting of SnSeS, SnSeTe, SnSTe, PbSeS, PbSeTe, PbSTe, SnPbS, SnPbSe, SnPbTe and mixtures thereof, and the quaternary compounds are selected from the group consisting of SnPbSSe, SnPbSeTe, SnPbSTe and mixtures thereof. The group IV element may be at least one selected from the group consisting of Si, Ge and mixtures thereof. The group IV compound may be a binary compound selected from the group consisting of SiC, SiGe and mixtures thereof.

In this case, the binary compound, the tertiary compound and/or the quaternary compound may exist in particles at a uniform (or substantially uniform) concentration, or may exist in the same particle divided into states where concentration distributions are partially different. Further, the particles may have a core/shell structure in which one quantum dot surrounds another quantum dot. An interface between the core and the shell may have a concentration gradient in which the concentration of elements present in the shell decreases toward the center.

In one or more embodiments, the quantum dot may have a core-shell structure including a core including the nanocrystal described above and a shell surrounding (e.g., around) the core. The shell of the quantum dot may serve as a protective layer for maintaining semiconductor characteristics by preventing or reducing chemical denaturation of the core and/or as a charging layer for giving electrophoretic characteristics to the quantum dot. The shell may be a single layer or a multilayer. Examples of the shell of the quantum dot may include a metal oxide, a non-metal oxide, a semiconductor compound, and a combination thereof.

For example, the metal oxide and/or the non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, and/or a tertiary compound such as MgAl₂O₄, CoFe₂O₄, NiFe₂O₄ and/or CoMn₂O₄, but the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb and/or the like, but is not limited thereto.

The scatterer may scatter light of the light emitting element LE in random directions. The scatterer may have a refractive index different from that of the first base resin BRS1 and may form an optical interface with the first base resin BRS1. For example, the scatterer may include (e.g., may be) light scattering particles. The scatterer is not particularly limited as long as it is a suitable material capable of scattering at least a portion of the transmitted light, and may be, for example, metal oxide particles and/or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and the like. Examples of a material of the organic particles may include acrylic resin, urethane resin, and the like. The scatterer may scatter light in random directions regardless of the incidence direction of the incident light, without substantially converting the wavelength of the light.

The second wavelength conversion layer WCL2 may be provided to overlap the second emission area EA2. The second wavelength conversion layer WCL2 may emit light by converting and/or shifting the peak wavelength of incident light to another set or specific peak wavelength. In one or more embodiments, the second wavelength conversion layer WCL2 may convert the first light that is blue light emitted from the light emitting element LE of the second emission area EA2 into the third light that is green light having a peak wavelength in the range of about 510 nm to 550 nm and emit the green light.

The second wavelength conversion layer WCL2 may include a second base resin BRS2 and second wavelength conversion particles WCP2 dispersed in the second base resin BRS2. The second wavelength conversion layer WCL2 may further include the scatterer.

The second base resin BRS2 may be made of a material having a relatively high light transmittance, and may be made of the same material as that of the first base resin BRS1, or may include at least one of the materials exemplified as the constituent materials thereof.

The second wavelength conversion particle WCP2 may convert and/or shift the peak wavelength of incident light to another set or specific peak wavelength. In one or more embodiments, the second wavelength conversion particle WCP2 may convert the first light that is blue light provided from the light emitting element LE into the third light that is green light having a peak wavelength in the range of about 510 nm to 550 nm and emit the green light. Examples of the second wavelength conversion particle WCP2 may include a quantum dot, a quantum rod, a phosphor, and the like. A more detailed description of the second wavelength conversion particle WCP2 is substantially the same as or similar to the description of the first wavelength conversion particle WCP1, and thus will not be provided again (e.g., will be omitted).

The light transmission layer WCL3 may be provided to overlap the third emission area EA3. The light transmission layer WCL3 may transmit incident light. The light transmission layer WCL3 may transmit the first light that is blue light emitted from the light emitting element LE provided in the third emission area EA3 without conversion. The light transmission layer WCL3 may include a third base resin BRS3. The light transmission layer WCL3 may further include the scatterers dispersed in the third base resin BRS3. Because the third base resin BRS3 is substantially the same as or similar to the above-described first base resin BRS1, a description thereof will not be provided again (e.g., will be omitted).

The wavelength controller WCP may further include the second capping layer CAP2 provided on the light blocking portion BM, the reflective layer RFL, and the wavelength conversion layer QDL. The second capping layer CAP2 serves to cover the wavelength conversion layer QDL provided thereunder and protect it from moisture and/or foreign substances. The second capping layer CAP2 may include an inorganic material, and may include a material substantially the same as or similar to that of the above-described first capping layer CAP1.

In one or more embodiments, a color filter layer CFL may be provided on the wavelength controller WCP. The first light, the second light, and the third light emitted from the above-described wavelength controller WCP may pass through the color filter layer CFL to realize a full color display. The color filter layer CFL may include a first overcoat layer OC1, a first color filter CF1, a second color filter CF2, a third color filter CF3, and a second overcoat layer OC2.

The first overcoat layer OC1 may be provided on the wavelength controller WCP. The first overcoat layer OC1 may be directly provided on the second capping layer CAP2 of the wavelength controller WCP. The first overcoat layer OC1 may be entirely provided in the display area DA, and may have a flat (or substantially flat) surface. The first overcoat layer OC1 may flatten (or substantially flatten) the stepped portion formed thereunder by the wavelength controller WCP to facilitate the formation of the color filter layer CFL.

The first overcoat layer OC1 may include a light transmitting organic material. For example, the first overcoat layer OC1 may include epoxy resin, acrylic resin, cardo resin, imide resin, and/or the like.

The first color filter CF1, the second color filter CF2, and the third color filter CF3 may be provided on the first overcoat layer OC1. The first color filter CF1 may be provided in the first emission area EA1, the second color filter CF2 may be provided in the second emission area EA2, and the third color filter CF3 may be provided in the third emission area EA3.

The first color filter CF1, the second color filter CF2, and the third color filter CF3 may include a colorant such as a dye and/or pigment that absorbs a wavelength other than a corresponding color wavelength. The first color filter CF1 may selectively transmit the second light (e.g., red light), and block, absorb, or reduce the first light (e.g., blue light) and the third light (e.g., green light). The second color filter CF2 may selectively transmit the third light (e.g., green light), and block, absorb, or reduce the first light (e.g., blue light) and the second light (e.g., red light). The third color filter CF3 may selectively transmit the first light (e.g., blue light), and block, absorb, or reduce the second light (e.g., red light) and the third light (e.g., green light). For example, the first color filter CF1 may be a red color filter, the second color filter CF2 may be a green color filter, and the third color filter CF3 may be a blue color filter.

In one or more embodiments, the light incident on the first color filter CF1 may be the second light converted by the first wavelength conversion layer WCL1, the light incident on the second color filter CF2 may be the third light converted by the second wavelength conversion layer WCL2, and the light incident on the third color filter CF3 may be the first light that has passed through the light transmission layer WCL3. As a result, the second light having passed through the first color filter CF1, the third light having passed through the second color filter CF2, and the first light having passed through the third color filter CF3 may be emitted upward from the substrate to realize a full color display.

The first color filter CF1, the second color filter CF2, and the third color filter CF3 may absorb a part of the light coming from the outside of the display device 10 to reduce the reflected light of the external light. Accordingly, the first color filter CF1, the second color filter CF2, and the third color filter CF3 may prevent or reduce color distortion caused by the reflection of the external light.

The second overcoat layer OC2 may be provided on the first to third color filters CF1, CF2, and CF3. The second overcoat layer OC2 may be directly provided on the first to third color filters CF1, CF2, and CF3. The second overcoat layer OC2 may be entirely provided in the display area DA, and may have a flat (or substantially flat) surface. The second overcoat layer OC2 may flatten (or substantially flatten) the stepped portion formed thereunder by the first to third color filters CF1, CF2, and CF3. The second overcoat layer OC2 may include a light transmitting organic material, and may be substantially the same as or similar to the above-described first overcoat layer OC1.

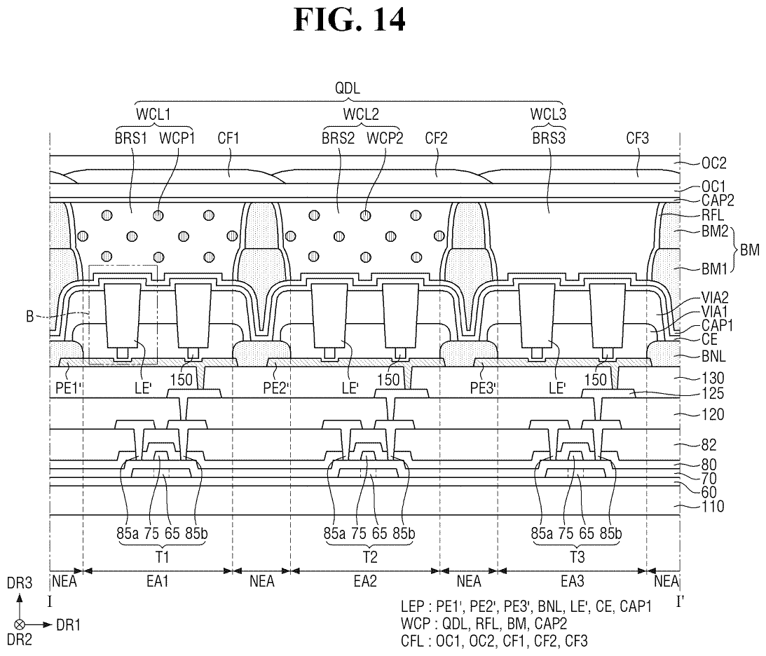

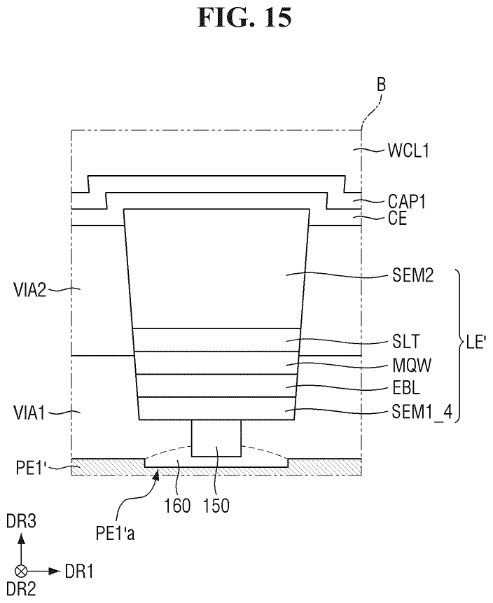

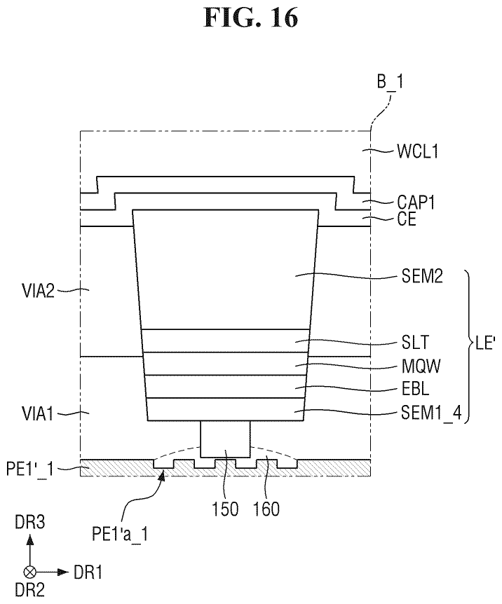

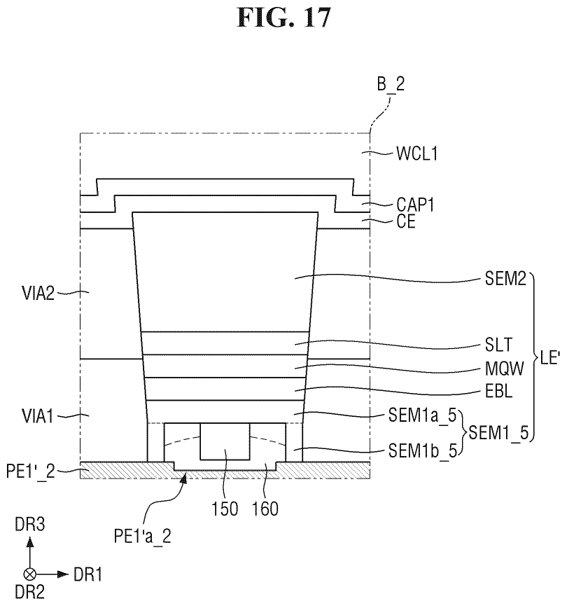

FIG. 14 is a cross-sectional view schematically illustrating a display device according to one or more embodiments. FIG. 15 is an enlarged view of area B of FIG. 14, and FIGS. 16 and 17 are enlarged views of area B according to one or more embodiments. In FIGS. 14 to 17, the same or similar reference numbers indicate the same or similar components.

Referring to FIGS. 14 to 16, one or more of these embodiments are different from the embodiments of FIGS. 5 to 12 described above in that pixel electrodes PE1′, PE2′, and PE3′ include grooves, and a light emitting element LE′ does not include a support portion. Referring to FIG. 17, it is different from the embodiments of FIGS. 5 to 12 described above in that the pixel electrodes PE1′, PE2′, and PE3′ include grooves. In the following description, redundant descriptions of the above-described embodiments may not be provided (e.g., will be omitted) while a focus on the differences will be made.

The pixel electrodes PE1′, PE2′, and PE3′ may include grooves PE1′a, PE2′a, and PE3′a, respectively. The adhesive layer 160 may be provided on the grooves PE1′a, PE2′a, and PE3′a of the pixel electrodes PE1′, PE2′, and PE3′ to connect the pixel electrodes PE1′, PE2′, and PE3′ to the connection electrode 150. The grooves PE1′a, PE2′a, and PE3′a may overlap the connection electrode 150, the light emitting element LE′, and the wavelength conversion layer QDL in the thickness direction of the substrate (the third direction DR3).

When the pixel electrodes PE1′, PE2′, and PE3′ include the grooves PE1′a, PE2′a, and PE3′a, the contact area between the adhesive layer 160 and the pixel electrodes PE1′, PE2′, and PE3′ increases. Additionally, the grooves PE1′a, PE2′a, and PE3′a may prevent or reduce the tilting of the light emitting element LE′ and may make (or help) it stand in the vertical (or substantially vertical) direction of the substrate. Accordingly, the bonding yield of the light emitting element LE′ may be improved, and the color purity and brightness of the display panel may be enhanced.

The cross-sectional shape of the grooves PE1′a, PE2′a, and PE3′a may be a polygonal shape such as a square, a semicircular shape, a semielliptical shape, and/or an arcuate shape.

The pixel electrodes PE1′, PE2′, and PE3′ may include a single or plural number of grooves PE1′a, PE2′a, and PE3′a that overlap one light emitting element LE′. For example, the pixel electrode PE1′ of FIG. 15 includes one groove PE1′a that overlaps the light emitting element LE′. The pixel electrode PE1′_1 of FIG. 16 includes a plurality of grooves PE1′a_1 that overlap the light emitting element LE′.

The pixel electrodes PE1′, PE2′, and PE3′ including the grooves PE1′a, PE2′a, and PE3′a may contain a metal material. The metal may include, e.g., copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. In some embodiments, the pixel electrodes PE1′, PE2′, and PE3′ may have a multi-layer structure in which two or more metal layers are stacked.

In one or more embodiments, the pixel electrodes PE1′, PE2′a, and PE3′ may include a titanium layer and a copper layer provided on the titanium layer. The grooves PE1′a, PE2′a, and PE3′a may be formed in the copper layer.

The adhesive layer 160 may be provided on the grooves PE1′a, PE2′a, and PE3′a of the pixel electrodes PE1′, PE2′, and PE3′. The width of the adhesive layer 160 may be the same as the width of each groove PE1′a, PE2′a, PE3′a, or may be larger than the width of each groove PE1′a, PE2′a, PE3′a. The width of each groove PE1′a, PE2′a, PE3′a may be smaller than the width of the light emitting element LE′.

In one or more embodiments, as shown in FIG. 17, a first semiconductor layer SEM1_5 of the light emitting element LE′, which is provided on a pixel electrode PE1′_2 including a groove PE1′a_2, may include a body portion SEM1a_5 adjacent to the active layer MQW and a support portion SEM1b_5 protruding from the body portion SEM1a_5 toward the pixel electrode PE1′_2. The support portion SEM1b_5 may be in contact with the pixel electrode PE1′_2. The support portion SEM1b_5 may not overlap the groove PE1′a_2 of the pixel electrode PE1′_2.

The support portion SEM1b_5 may include a first pillar and a second pillar facing the first pillar. The width of the groove PE1′a_2 of the pixel electrode PE1′_2 may be the same as or smaller than the distance between the first pillar and the second pillar.

Hereinafter, a manufacturing process of the display device 10 according to one or more embodiments will be described with reference to other drawings.

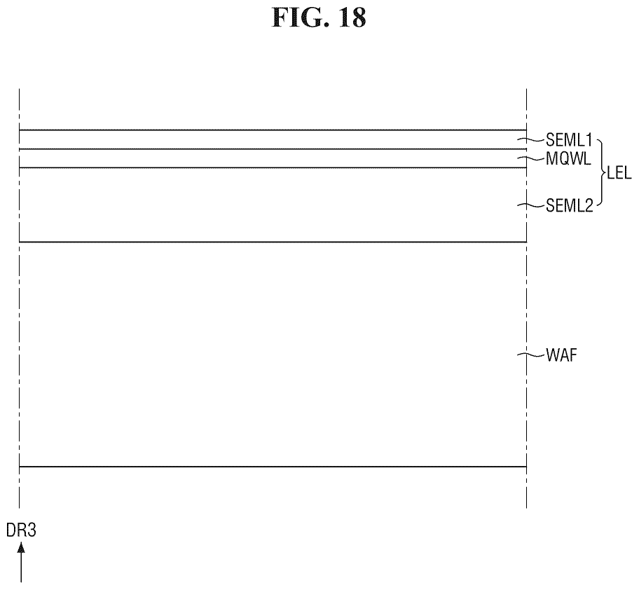

FIGS. 18 to 30 are diagrams illustrating a method of manufacturing a display device according to one or more embodiments.

FIGS. 18 to 30 are cross-sectional views illustrating structures corresponding to the sequence of formation of the respective layers of the display device 10. FIGS. 18 to 30 mainly illustrate manufacturing processes of the light emitting element portion LEP and the wavelength controller WCP, and each may generally correspond to the cross-sectional view of FIG. 5. In addition, the drawings are related to the embodiments of FIGS. 5 to 12. By partially changing the manufacturing processes, the display device of the embodiments of FIGS. 14 to 17 may be manufactured. Further, hereinafter, the first emission area EA1 of the display device 10 will be mainly described.

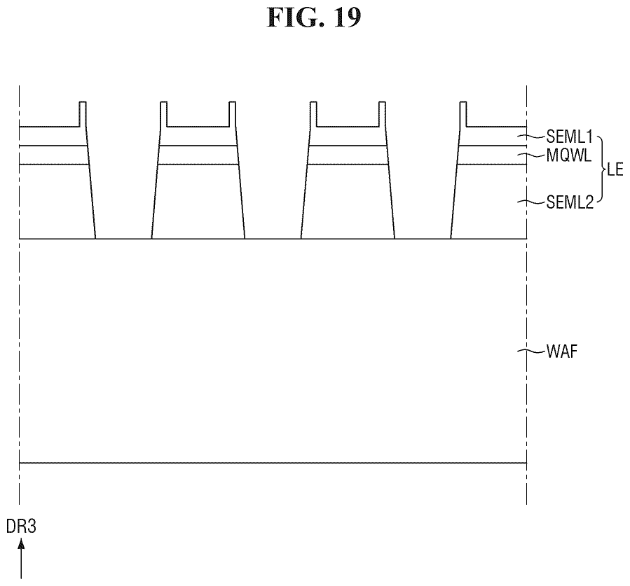

Referring to FIGS. 18 and 19, the plurality of light emitting element layers LEL are formed on a base substrate WAF.

For example, the base substrate WAF is prepared. The base substrate WAF may be a sapphire substrate (Al₂O₃) and/or a silicon wafer containing silicon. However, the present disclosure is not limited thereto, and in one or more embodiments, a case in which the base substrate WAF is a sapphire substrate will be described as an example.

A plurality of semiconductor material layers SEML1, MQWL, SEML2 are formed on the base substrate WAF. In FIGS. 18 to 30, an electron blocking layer and a superlattice layer are not included (e.g., are omitted). The plurality of semiconductor material layers grown by an epitaxial method may be formed by growing seed crystals. Here, the semiconductor material layer may be formed utilizing at least one of electron beam deposition, physical vapor deposition (PVD), chemical vapor deposition (CVD), plasma laser deposition (PLD), dual-type thermal evaporation, sputtering, and metal organic chemical vapor deposition (MOCVD), for example, by utilizing the metal organic chemical vapor deposition (MOCVD). However, the present disclosure is not limited thereto.

A precursor material for forming the plurality of semiconductor material layers may be selected to form a target material in a suitably selectable range without any limitation. For example, the precursor material may be a metal precursor including an alkyl group such as a methyl group and/or an ethyl group. Examples of the precursor material may include, but are not limited to, trimethylgallium Ga(CH₃)₃, trimethylaluminum Al(CH₃)₃, and triethyl phosphate (C₂H₅)₃PO₄.

For example, the second semiconductor material layer SEML2 may be formed on the base substrate WAF. Although it is shown in the drawing that one second semiconductor material layer SEML2 is deposited, the present disclosure is not limited thereto, and a plurality of layers may be formed.

The active material layer MQWL and the first semiconductor material layer SEML1 are sequentially formed on the second semiconductor material layer SEML2 utilizing any of the aforementioned methods.

Next, as shown in FIG. 19, the plurality of semiconductor material layers SEML2, MQWL, and SEML1 are etched, and the first semiconductor material layer SEML1 is partially etched to form a support portion. In order to obtain the light emitting element LE′ that does not include a support portion as shown in FIGS. 15 and 16, the process of partially etching the first semiconductor material layer SEML1 may be omitted.

The semiconductor material layers may be etched by any suitable method. For example, the process of etching the semiconductor material layers may be performed by a dry etching method, a wet etching method, a reactive ion etching (RIE) method, a deep reactive ion etching (DRIE) method, an inductively coupled plasma reactive ion etching (ICP-RIE) method, and/or the like. The dry etching method may be suitable for vertical etching because anisotropic etching can be performed. In the case of utilizing the aforementioned etching technique, it may be possible to use Cl₂ and/or O₂ as an etchant. However, the present disclosure is not limited thereto.

Through these processes, a plurality of light emitting elements LE may be obtained. Accordingly, the plurality of light emitting elements LE are formed by including the second semiconductor layer SEM2, the active layer MQW, and the first semiconductor layer SEM1.

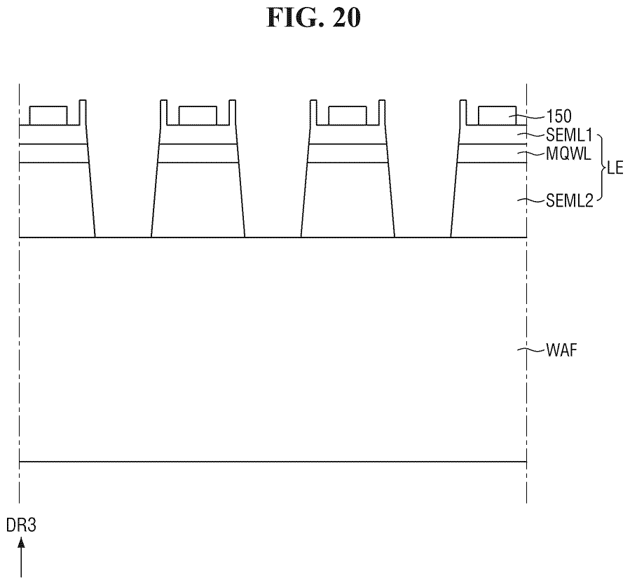

Next, referring to FIG. 20, the connection electrode 150 is formed on the first semiconductor layer SEM1 of the light emitting element LE.

The connection electrode 150 may be formed between the support portions on the first semiconductor layer SEM1 by stacking an electrode material layer on the base substrate WAF and then etching it through an etching process.

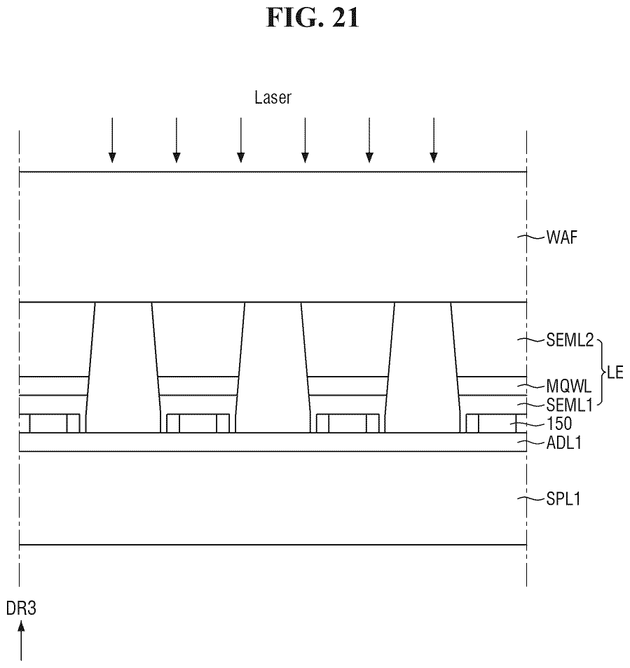

Next, referring to FIG. 21, a first support film SPL1 is attached on the plurality of light emitting elements LE of the base substrate WAF manufactured in FIG. 20. In this case, a first tackifying layer ADL1 may be interposed between the first support film SPL1 and the light emitting element LE.

The first tackifying layer ADL1 may be aligned on the plurality of light emitting elements LE and attached to the connection electrodes 150 and/or the support portions of the plurality of light emitting elements LE. Because the plurality of light emitting elements LE are provided in relatively large numbers, they may be attached to the first tackifying layer ADL1 without being detached.

The first support film SPL1 may be made of a material that is transparent and has suitable mechanical stability to allow light to pass therethrough. For example, the first support film SPL1 may include a transparent polymer such as polyester, polyacrylic, polyepoxy, polyethylene, polystyrene, polyethylene terephthalate, and/or the like. The first tackifying layer ADL1 may include a tackifying material for adhering the light emitting element LE. For example, the tackifying material may include urethane acrylates, epoxy acrylates, polyester acrylates, and/or the like. The tackifying material may be a material whose tackiness changes as ultraviolet (UV) and/or heat is applied, and thus the tackifying layer may be easily or suitably separated from the light emitting element LE.

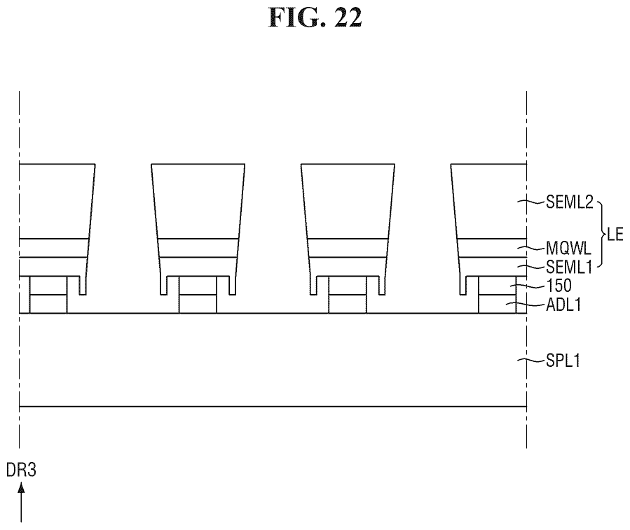

Subsequently, referring to FIGS. 21 and 22, the light emitting elements LE are separated from the base substrate WAF by irradiating the base substrate WAF with a laser (1^{st} laser). The base substrate WAF is separated from each of the second semiconductor material layers SEML2 of the plurality of light emitting elements LE.

The process of separating the base substrate WAF may be a laser lift off (LLO) process. In the laser lift off process utilizing laser, KrF excimer laser (248 nm wavelength) may be utilized as a source. The energy density of the excimer laser is irradiated in the range of about 550 mJ/cm² to 950 mJ/cm², and the incident area may be in the range of 50×50 μm² to 1×1 cm², but the present disclosure is not limited thereto. By irradiating the laser to the base substrate WAF, the base substrate WAF may be separated from the light emitting element LE.

Next, referring to FIG. 22, areas of the first tackifying layer ADL1, which do not overlap the light emitting element LE (e.g., areas of the first tackifying layer ADL1, which do not overlap the corresponding connection electrodes 150), are etched.

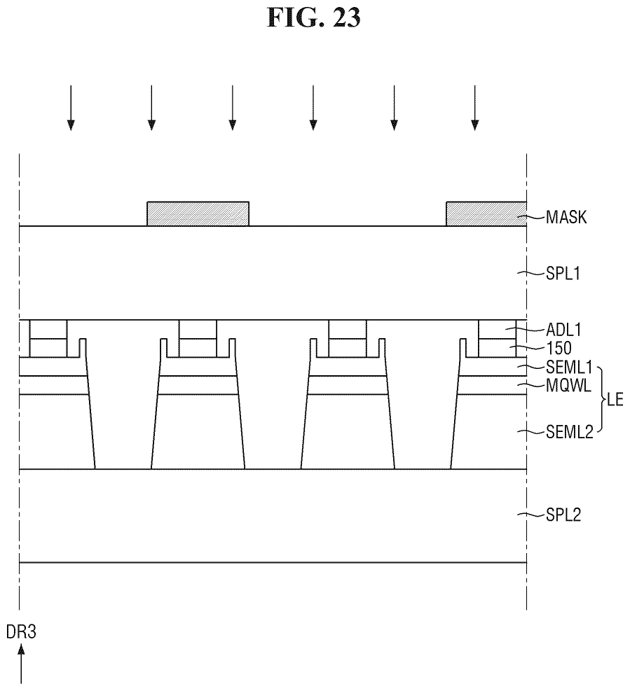

Next, referring to FIG. 23, the first support film SPL1 is aligned on an interposer substrate SPL2. The interposer substrate SPL2 may be configured with a second support layer and a second tackifying layer provided on the second support layer. The second support layer may be made of a material that is suitably mechanically stable and transparent to allow light to pass therethrough. As a material of the second support layer, any of the materials exemplified for the first support film SPL1 may be applied. The second tackifying layer may include a tackifying material for adhering the light emitting element LE. As a material of the second tackifying layer, any of the materials exemplified for the first tackifying layer ADL1 may be applied.

Thereafter, the desired light emitting element LE may be selectively transferred to the interposer substrate SPL2 utilizing a mask MASK and a laser. In this case, the first tackifying layer ADL1 is removed from the connection electrode 150.

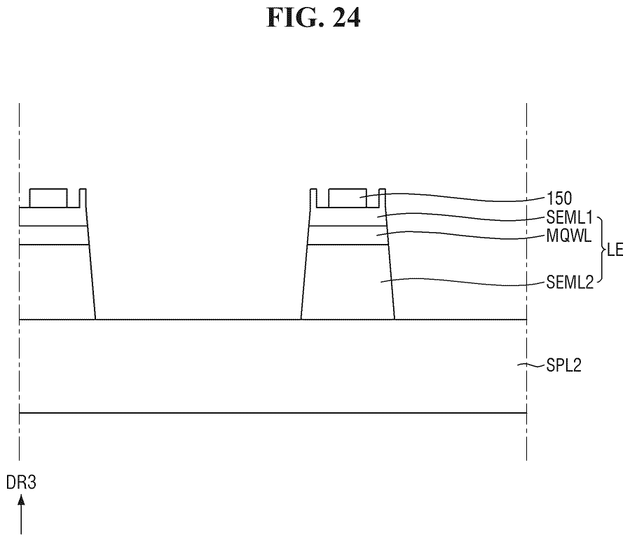

Referring to FIG. 24, the light emitting element LE, which had not been covered with the mask MASK, was transferred to the interposer substrate SPL2 by a laser.

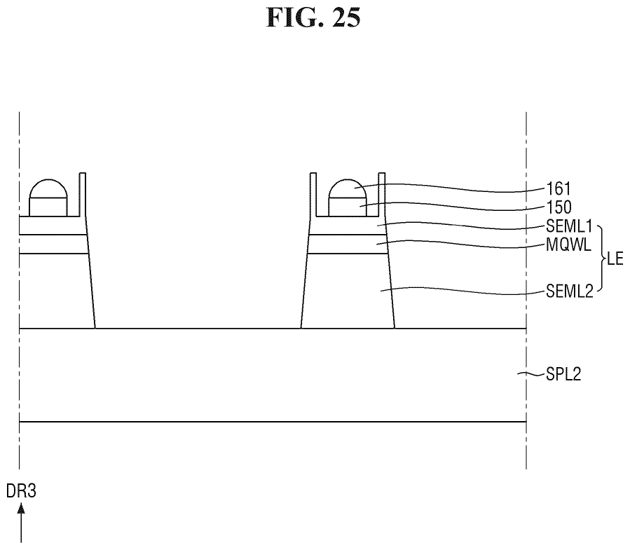

Next, referring to FIG. 25, an adhesive layer material 161 is deposited on the transferred light emitting element LE and connection electrode 150. In one or more embodiments, the adhesive layer material 161 may be solder. The solder may be at least one of, or an alloy of two or more of, gold (Au), copper (Cu), tin (Sn), titanium (Ti), aluminum (Al), and silver (Ag). The adhesive layer material 161 is provided between or in the support portions of the light emitting element LE. When the adhesive layer material 161 includes a high content of tin (Sn), the deposition control may be relatively difficult and thus a variation may occur in the size and/or arrangement/alignment of the adhesive layer material 161.

Through the processes of FIGS. 18 to 25, the light emitting element LE may be manufactured and transferred to the interposer substrate SPL2.

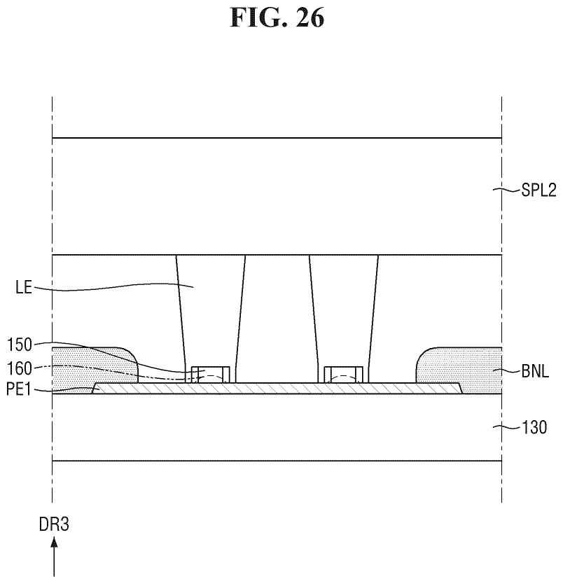

Next, referring to FIG. 26, the substrate, on which the bank layer BNL and the pixel electrodes PE1, PE2, and PE3 are provided, is prepared (including the second planarization layer 130), and the interposer substrate SPL2 is attached to the substrate 110 such that the connection electrodes 150 of the light emitting elements LE are in contact with the pixel electrodes PE1, PE2, and PE3.

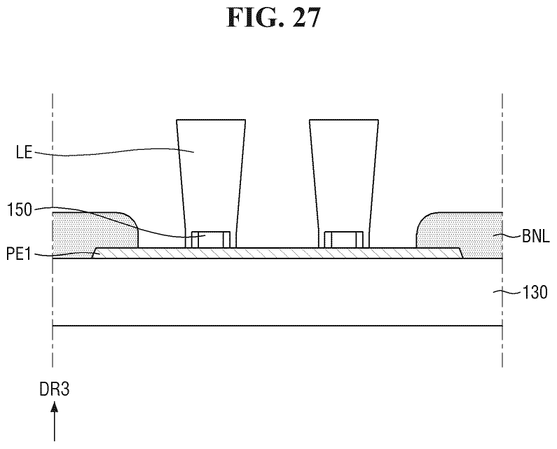

The adhesive layer material 161 is melted by applying heat and pressure and/or irradiating a laser to bond the pixel electrodes PE1, PE2, and PE3 to the plurality of light emitting elements LE. Thereafter, the interposer substrate SPL2 is detached as shown in FIG. 27.

FIGS. 27 to 30 mainly show manufacturing processes of the light emitting element portion LEP and the wavelength controller WCP, and the adhesive layer 160 provided under the light emitting element LE is omitted (e.g., is not shown).

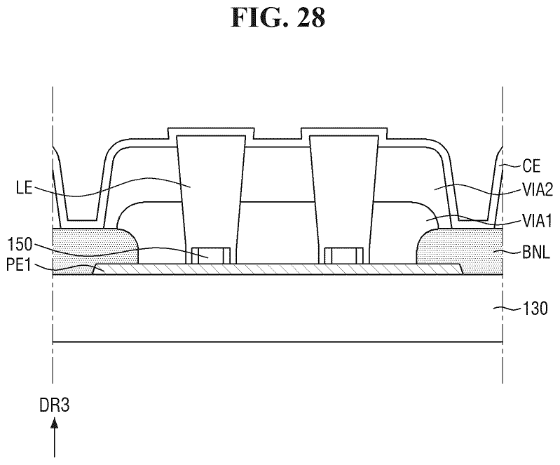

Referring to FIG. 28, the via layers VIA1 and VIA2 are formed to flatten (or substantially flatten) a stepped portion due to the plurality of light emitting elements LE, and the common electrode CE is formed on the via layers VIA1 and VIA2 and the plurality of light emitting elements LE. A via layer may include the first via layer VIA1 and the second via layer VIA2.

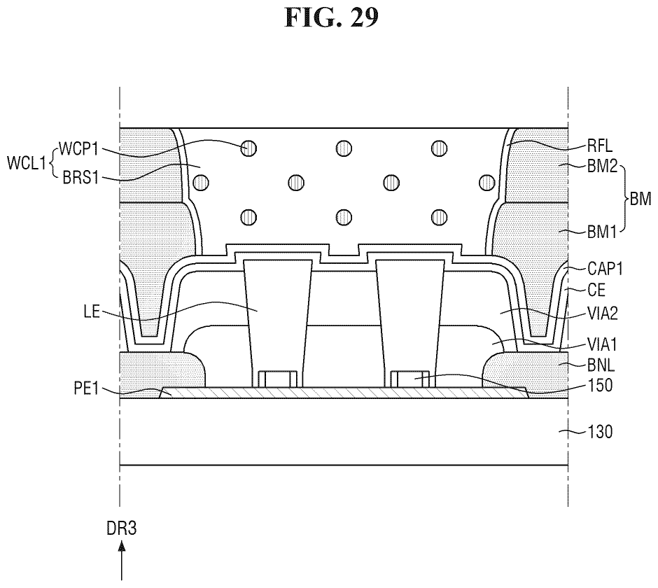

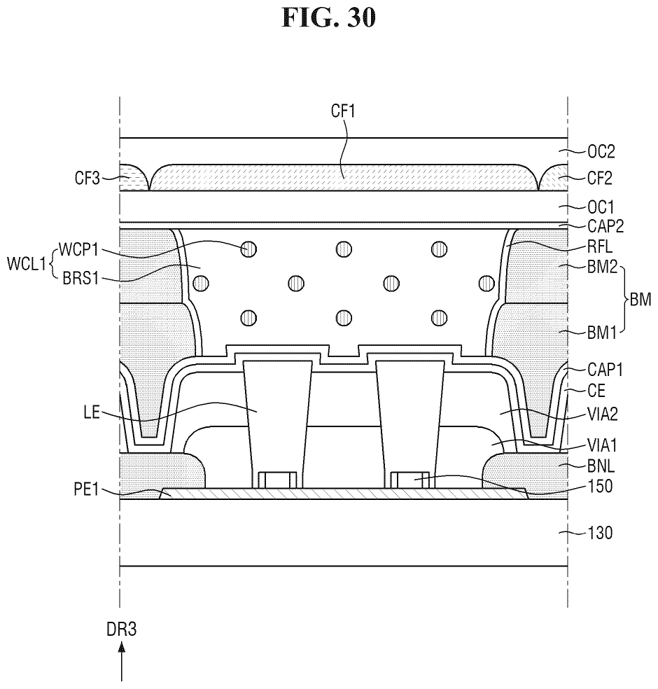

Next, as shown in FIG. 29, the first capping layer CAP1 is formed on the common electrode CE, and then the light blocking portion BM, the reflective layer RFL, and the first wavelength conversion layer WCL1 are formed on the first capping layer CAP1. Subsequently, as shown in FIG. 30, the second capping layer CAP2 and the first overcoat layer OC1 are formed on the light blocking portion BM, the reflective layer RFL, and the first wavelength conversion layer WCL1, and the plurality of color filters CF1, CF2, and CF3 are formed on the first overcoat layer OC1. Thereafter, the second overcoat layer OC2 is formed on the color filters CF1, CF2, and CF3.

With reference to FIGS. 18 to 30, the manufacturing processes of the display device including the support portion in the light emitting element LE have been described. The etching process of the first semiconductor material layer SEML1 for forming the support portion shown in FIG. 19 may be omitted, and the first pixel electrode PE1 may be partially etched to form a groove as shown in FIG. 26. By modifying this process, a display device including a pixel electrode having a groove may be manufactured.

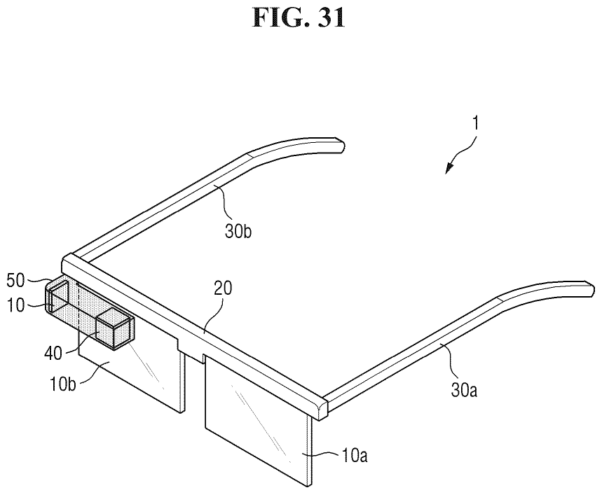

FIG. 31 is an example diagram illustrating a virtual reality device including a display device according to one or more embodiments. FIG. 31 illustrates a virtual reality device 1 to which the display device 10 according to one or more embodiments is applied.

Referring to FIG. 31, the virtual reality device 1 according to one or more embodiments may be a glass-type device (e.g., glasses). The virtual reality device 1 according to one or more embodiments may include the display device 10, a left lens 10a, a right lens 10b, a support frame 20, temples 30a and 30b, a reflection member 40, and a display device storage 50.

Although FIG. 31 illustrates the virtual reality device 1 including the temples 30a and 30b, the virtual reality device 1 according to one or more embodiments may be applied to a head mounted display including a head mounted band that may be worn on a head, instead of the temples 30a and 30b. That is, the virtual reality device 1 according to one or more embodiments is not limited to that shown in FIG. 31, and may be applied in various suitable forms to various suitable electronic devices.

The display device storage 50 may include the display device 10 and the reflection member 40. The image displayed on the display device 10 may be reflected by the reflection member 40 and provided to a user's right eye through the right lens 10b. Accordingly, the user can view the virtual reality image displayed on the display device 10 through the right eye.

FIG. 31 illustrates that the display device storage 50 is provided at the right end of the support frame 20, but the embodiment of the present disclosure is not limited thereto. For example, the display device storage 50 may be provided at the left end of the support frame 20, and in this case, the image displayed on the display device 10 may be reflected by the reflection member 40 and provided to a user's left eye through the left lens 10a. Accordingly, the user can view the virtual reality image displayed on the display device 10 through the left eye. In some embodiments, the display device storage 50 may be provided at both the left end and the right end of the support frame 20. In that case, the user can view the virtual reality image displayed on the display device 10 through both the left eye and the right eye.

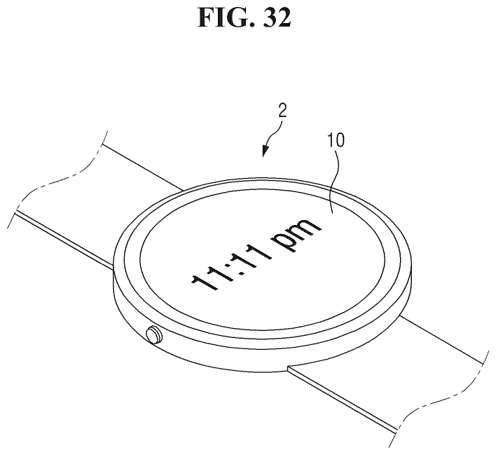

FIG. 32 is an example diagram illustrating a smart device (e.g., a smart watch 2) including a display device according to one or more embodiments.

Referring to FIG. 32, the display device 10 according to one or more embodiments may be applied to the smart watch 2 that is one of the smart devices.

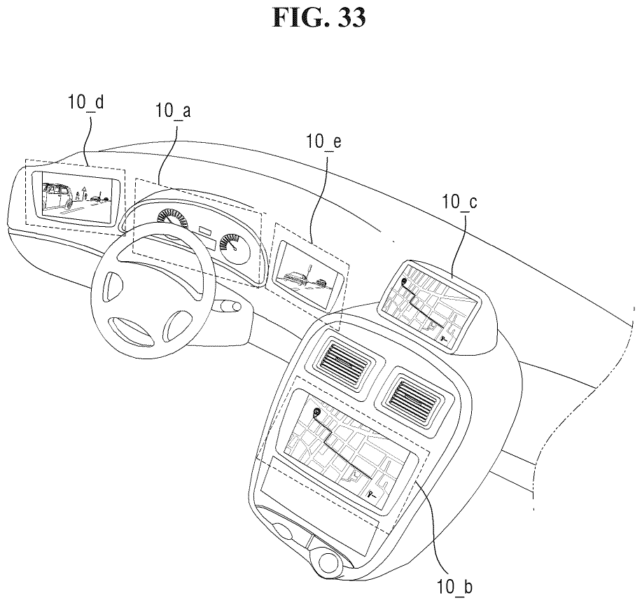

FIG. 33 is an example diagram illustrating a portion of a vehicle (e.g., an automobile) including the display device according to one or more embodiments. FIG. 33 shows a portion of a vehicle (e.g., an automobile) to which the display device 10 according to one or more embodiments is applied.

Referring to FIG. 33, the display devices 10_a, 10_b, and 10_c according to one or more embodiments may be applied to the dashboard of the vehicle (e.g., automobile), the center fascia of the vehicle (e.g., automobile), and/or the center information display (CID) of the dashboard of the vehicle (e.g., automobile). In one or more embodiments, the display devices 10_d and 10_e according to one or more embodiments may be applied to a room mirror display (e.g., included on the dashboard of the vehicle (e.g., automobile)) instead of side mirrors of the vehicle (e.g., automobile).

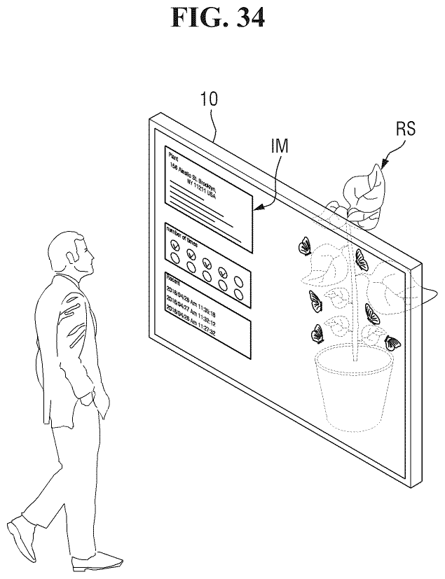

FIG. 34 is an example diagram illustrating a transparent display device including a display device according to one or more embodiments.

Referring to FIG. 34, the display device 10 according to one or more embodiments may be applied to the transparent display device. The transparent display device may display an image IM, and also may transmit light. Thus, a user located at the front side of the transparent display device can view an object RS and/or a background on the rear side of the transparent display device as well as the image IM displayed on the display device 10. When the display device 10 is applied to the transparent display device, the substrate 110 of the display device 10 may include a light transmitting portion capable of transmitting light and/or may be made of a material capable of transmitting light.

In concluding the detailed description, those skilled in the art will appreciate that many variations and modifications can be made to the present embodiments without substantially departing from the principles of the present disclosure, as set forth in the following claims and their equivalents. Therefore, the disclosed embodiments of the present disclosure are used in a generic and descriptive sense only and not for purposes of limitation.

What is claimed is:

1. A display device comprising:
a substrate;
a pixel electrode on the substrate;
a light emitting element on the pixel electrode, the light emitting element comprising a first semiconductor layer, a second semiconductor layer, and an active layer between the first semiconductor layer and the second semiconductor layer;
a connection electrode between the pixel electrode and the light emitting element;
an adhesive layer between the connection electrode and the pixel electrode; and
a common electrode on the light emitting element,
wherein the first semiconductor layer comprises a body portion adjacent to the active layer, and a support portion protruding from the body portion toward the pixel electrode, and
the adhesive layer overlaps the support portion of the first semiconductor layer in a horizontal direction of the substrate.

2. The display device of claim 1, wherein the support portion of the first semiconductor layer is at a position adjacent to an edge of the body portion.

3. The display device of claim 1, wherein a thickness of the support portion of the first semiconductor layer is equal to or greater than a thickness of the connection electrode.

4. The display device of claim 1, wherein the support portion of the first semiconductor layer is in contact with the pixel electrode.

5. The display device of claim 1, wherein the body portion and the support portion of the first semiconductor layer are integral with each other.

6. The display device of claim 1, wherein the connection electrode is surrounded by the support portion.

7. The display device of claim 1, wherein the support portion of the first semiconductor layer comprises a first pillar, and a second pillar facing the first pillar, and
the adhesive layer and the connection electrode are between the first pillar and the second pillar of the support portion.

8. The display device of claim 7, wherein the first pillar and the second pillar are spaced apart from each other in a plan view.

9. The display device of claim 8, wherein a width of the adhesive layer is greater than a distance between the first pillar and the second pillar.

10. The display device of claim 6, wherein a space between the body portion of the first semiconductor layer and the adhesive layer is empty.

11. The display device of claim 7, wherein a space between the body portion of the first semiconductor layer and the adhesive layer is empty or comprises a via layer.

12. The display device of claim 1, wherein a cross section of the support portion of the first semiconductor layer is square, pentagonal, or hexagonal.

13. The display device of claim 1, wherein the adhesive layer comprises solder.

14. The display device of claim 1, wherein the pixel electrode comprises glass.

15. A display device comprising:
a substrate;
a first pixel electrode on the substrate and comprising a groove;
an adhesive layer on the groove of the first pixel electrode;
a connection electrode on the adhesive layer;
a first light emitting element on the connection electrode, and comprising a first semiconductor layer, a second semiconductor layer, and an active layer between the first semiconductor layer and the second semiconductor layer;
a common electrode on the first light emitting element; and
a first wavelength conversion layer on the common electrode, the first wavelength conversion layer overlapping the first light emitting element,
wherein the connection electrode, the first light emitting element, and the first wavelength conversion layer overlap the groove of the first pixel electrode.

16. The display device of claim 15, wherein a width of the adhesive layer is equal to or greater than a width of the groove of the first pixel electrode.

17. The display device of claim 15, further comprising:
a bank layer on the first pixel electrode, the bank layer not overlapping the groove of the first pixel electrode; and
a light blocking layer on the common electrode, the light blocking layer overlapping the bank layer.

18. The display device of claim 15, further comprising:
a second pixel electrode on the substrate and spaced apart from the first pixel electrode;
a second light emitting element on the connection electrode, and comprising a first semiconductor layer, a second semiconductor layer, and an active layer between the first semiconductor layer and the second semiconductor layer; and
a light transmission layer on the common electrode, the light transmission layer overlapping the second light emitting element.

19. The display device of claim 15, wherein the first semiconductor layer of the first light emitting element comprises a body portion adjacent to the active layer, and a support portion protruding from the body portion toward the first pixel electrode, and
the support portion is in contact with the first pixel electrode.

20. The display device of claim 19, wherein the support portion of the first semiconductor layer comprises a first pillar, and a second pillar facing the first pillar, and
a width of the groove of the first pixel electrode is equal to or smaller than a distance between the first pillar and the second pillar.
